(19) United States
(12) Patent Application Publication
(10) Pub. No.: US 2026/0353790 A1
(43) Pub. Date: Nov. 5, 2026

(54) SEMICONDUCTOR DEVICE AND METHOD OF MANUFACTURING THE SAME

(71) Applicant: Samsung Electronics Co., Ltd., Suwon-si (KR)

(72) Inventors: Yang Xu, Suwon-si (KR); Jinbum Kim, Suwon-si (KR); Soomin Son, Suwon-si (KR); Suk Yang, Suwon-si (KR); Dohyeon Lee, Suwon-si (KR); Sangmoon Lee, Suwon-si (KR); Changyong Han, Suwon-si (KR)

(73) Assignee: Samsung Electronics Co., Ltd., Suwon-si (KR)

(21) Appl. No.: 19/650,161

(22) Filed: Apr. 16, 2026

(30) Foreign Application Priority Data
May 2, 2025 (KR) 10-2025-0058473

(51) Int. Cl. H10D 84/85; H10D 84/01

(52) U.S. Cl. CPC H10D 84/856; H10D 84/0167; H10D 84/017; H10D 84/0186; H10D 84/0188; H10D 84/851

(57) ABSTRACT

A semiconductor device includes first source/drain patterns disposed at a first level in a substantially vertical direction on a substrate, a first channel pattern connected to the first source/drain patterns, second source/drain patterns disposed at a second level higher than the first level, a second channel pattern connected to the second source/drain patterns, a gate electrode on the first and second channel patterns, and a contact substantially vertically connected to at least one of the first and second source/drain patterns. The contact may be provided in a bottleneck shape having a smaller diameter at the second level than a diameter at levels other than the second level.

### CROSS-REFERENCE TO RELATED APPLICATIONS

This present application claims priority to and the benefit under 35 USC § 119(a)-(d) of Korean Patent Application No. 10-2025-0058473, filed on May 2, 2025, in the Korean Intellectual Property Office, the entire disclosure of which is incorporated herein by reference.

### FIELD

Embodiments of the present disclosure relate to a semiconductor device and a method of manufacturing the same, and more particularly, to a semiconductor device including a field effect transistor and a method of manufacturing the same.

### BACKGROUND

A semiconductor device includes an integrated circuit including metal oxide semiconductor field-effect transistors (MOSFETs). As the size and design rule of semiconductor devices are gradually scaled down, the scaling down of MOSFETs is also accelerating. A reduction in the size of MOSFETs may degrade the operating characteristics of the semiconductor device. Accordingly, there are ongoing research into various method of forming a semiconductor device having improved performance while reducing issues caused by the high integration of the semiconductor device.

### SUMMARY

Embodiments of the present disclosure provide a field-effect transistor semiconductor device configured to provide stable performance and improved reliability.

According to one or more embodiments, a semiconductor device includes first source/drain patterns disposed at a first level in a substantially vertical direction on a substrate, a first channel pattern connected to the first source/drain patterns, second source/drain patterns disposed at a second level higher than the first level, a second channel pattern connected to the second source/drain patterns, a gate electrode on the first and second channel patterns, and a contact substantially vertically connected to at least one of the first and second source/drain patterns. The contact may be provided in a bottleneck shape having a smaller diameter at the second level than a diameter at levels other than the second level.

According to one or more embodiments, a contact structure includes a first source/drain pattern, a second source/drain pattern stacked on the first source/drain pattern, and a contact penetrating through the second source/drain pattern and provided in a recess recessed from an upper surface of the first source/drain pattern. The contact may be provided in a bottleneck structure having a first diameter at a point in the first source/drain pattern and a second diameter smaller than the first diameter at a point in the second source/drain pattern.

According to one or more embodiments, a semiconductor device includes a first transistor provided on a substrate and including a first source/drain pattern, a second transistor stacked on the first transistor and including a second source/drain pattern overlapping the first source/drain pattern, and a contact disposed substantially vertically within the first and second source/drain patterns. The second source/drain pattern may include a first epitaxial layer having a first impurity concentration, a second epitaxial layer having a second impurity concentration higher than the first impurity concentration, and a third epitaxial layer protruding inwardly of the contact and having a third impurity concentration higher than the first impurity concentration. The contact may have a smaller diameter in a region, in which the third epitaxial layer is provided, than a diameter in another region adjacent to the region.

According to one or more embodiments, a method of manufacturing a semiconductor device includes forming a first source/drain pattern at a first level in a substantially vertical direction on a substrate, forming a second source/drain pattern disposed at a second level higher than the first level and vertically overlapping the first source/drain pattern, and forming a contact substantially vertically connected to at least one of the first and second source/drain patterns. The contact may be formed in a bottleneck shape having a smaller diameter at the second level than at levels other than the second level.

The forming of the contact may include a first contact forming operation of forming the contact in the first source/drain pattern. The first contact forming operation may include forming a recess in a substantially vertical direction within the first and second source/drain patterns, forming a first sacrificial insulating layer within the recess; removing a portion of the first sacrificial insulating layer to form a second sacrificial insulating layer exposing a side surface of the second source/drain pattern, forming an epitaxial layer protruding inwardly of the recess in a substantially horizontal direction from the side surface of the second source/drain pattern, removing the second sacrificial insulating layer, and forming a conductive material within the recess.

A thickness of the first sacrificial insulating layer on the first source/drain pattern may be greater than a thickness of the second sacrificial insulating layer on the second source/drain pattern.

The removing of the portion of the first sacrificial insulating layer may include removing the first sacrificial insulating layer on the first source/drain pattern.

The portion of the first sacrificial insulating layer may be removed by dry etching.

The method may further include forming an ohmic contact layer on the protruding epitaxial layer.

The forming of the conductive material within the recess may be performed by chemical vapor deposition.

The method may further include forming a second contact forming operation of forming the contact in the second source/drain pattern. The second contact forming operation may include forming an additional recess in a substantially vertical direction within the second source/drain pattern and forming a conductive material within the additional recess.

The method may further include a second contact forming operation of forming the contact in the second source/drain contact. The second contact forming operation may include forming an epitaxial layer protruding inwardly of the recess in a horizontal direction from a side surface of the second source/drain pattern and forming a conductive material within the recess.

The method may further include forming a first channel pattern and a second channel pattern substantially vertically overlapping on the substrate and forming a gate electrode on the first channel pattern and the second channel pattern.

### BRIEF DESCRIPTION OF THE DRAWINGS

FIG. 1 is a perspective view of a semiconductor chip according to one or more embodiments.

FIG. 2A is a cross-sectional view taken along line A-A′ of FIG. 1, and FIG. 2B is a cross-sectional view taken along line B-B′ of FIG. 1.

FIG. 3 is a part of a cross-sectional view illustrating a single contact, and is an enlarged cross-sectional view of the portion P1 of FIG. 2A.

FIGS. 4A to 21 are views, sequentially illustrating a method of manufacturing a semiconductor device according to one or more embodiments. FIGS. 4A, 5A, 6 TO 10, 11A, 12A, 13A, 14A, and 15 to 21 are cross-sectional views taken along line A-A′ of FIG. 1, and FIGS. 4B, 5B, 11B, 12B, 13B, and 14B are cross-sectional views taken along line B-B′ of FIG. 1.

### DETAILED DESCRIPTION

The following description with reference to the accompanying drawings is provided to assist in a comprehensive understanding of various embodiments of the present disclosure.

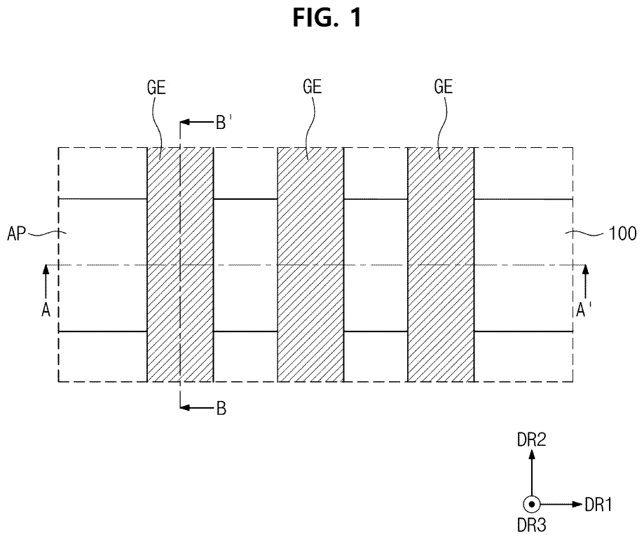

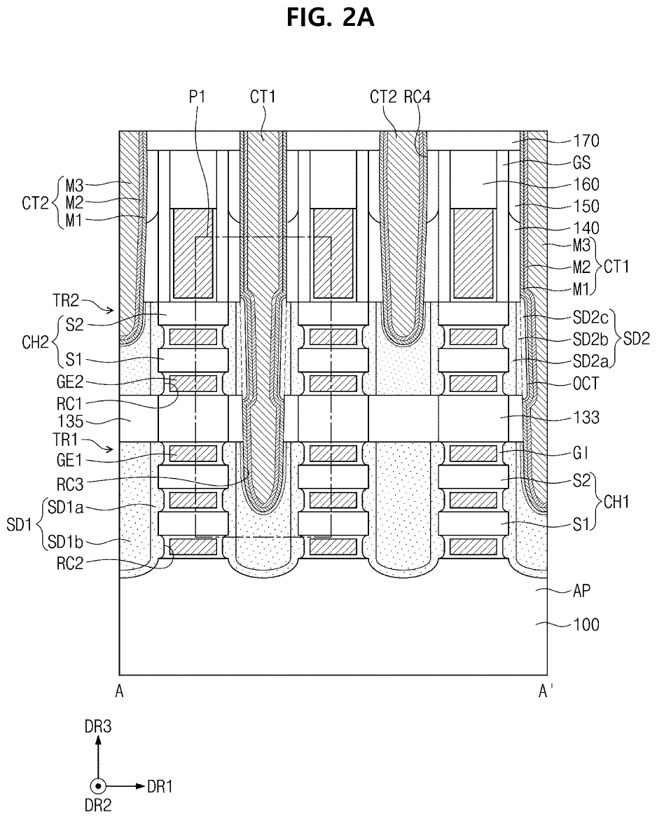

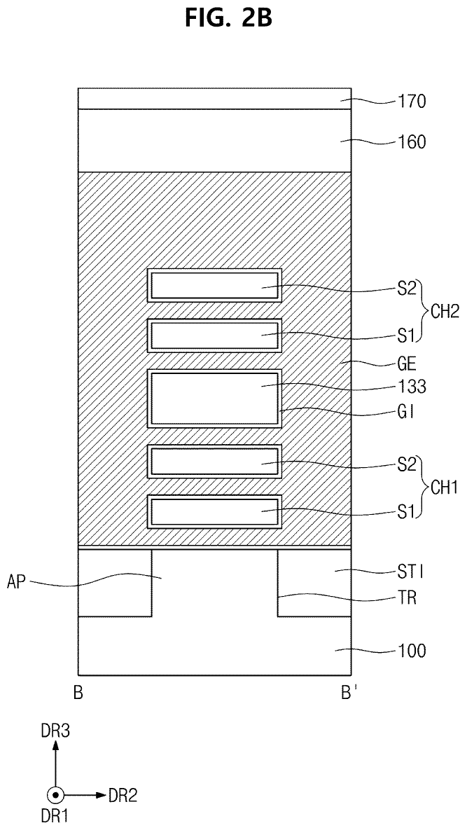

FIG. 1 is a plan view illustrating a semiconductor device according to one or more embodiments. FIG. 2A is a cross-sectional view taken along line A-A′ of FIG. 1, and FIG. 2B is a cross-sectional view taken along line B-B′ of FIG. 1.

Referring to FIGS. 1, 2A, and 2B, a semiconductor device may include a plurality of active patterns AP protruding in a vertical direction (a third direction DR3) from a substrate 100 and extending in a first horizontal direction (a first direction DR1), a first transistor TR1 disposed on a first vertical level on the active patterns AP, and a second transistor TR2 disposed on a second vertical level higher than the first vertical level on the active patterns AP. The first transistor TR1 and the second transistor TR2 may be disposed to overlap one another in the vertical direction, for example, the third direction DR3. A second direction DR2, which is not described herein, is a direction perpendicular to both the first direction DR1 and the third direction DR3. The term “level” used in the present disclosure refers to a distance in the vertical direction (the third direction DR3 or a direction opposite to the third direction DR3) from an upper surface of the substrate 100.

The substrate 100 may include a semiconductor such as Si or Ge, or a compound semiconductor such as SiGe, SiC, GaAs, InAs, InGaAs, or InP. The terms “SiGe,” “SiC,” “GaAs,” “InAs,” “InGaAs,” and “InP” as used herein refer to materials composed of the elements included in the respective terms, and are not chemical formulas representing stoichiometric relationships.

A first pattern CH1 and a second channel pattern CH2, providing a channel region of the first transistor TR1 and the second transistor TR2, may be disposed on the active pattern AP.

The first transistor TR1 may include a plurality of the first channel patterns CH1 disposed on the active pattern AP, a pair of first source/drain patterns SD1 disposed on opposite sides of the first channel pattern CH1 and in contact with each of the first channel patterns CH1, and a first gate electrode GE1 provided on the first channel pattern CH1. A pair of the first source/drain patterns SD1 constituting the first transistor TR1 may each fill a second recess RC2 formed on the active pattern AP. The first channel pattern CH1 may be disposed at a first separation distance vertically above the upper surface of the active pattern AP. The first gate electrode GE1 may surround each of the corresponding semiconductor patterns S1 and S2 within the first channel pattern CH1.

The second transistor TR2 may include a plurality of second channel patterns CH2 arranged in the second distance DR2 (in the third direction DR3) vertically upward from an upper surface of the active pattern AP at a second distance greater than the first distance, a pair of second source/drain patterns SD2 disposed on opposite sides of the second channel pattern CH2 and in contact with each of the second channel patterns CH2, and a second gate electrode GE2 provided on the second channel pattern CH2. The second channel pattern CH2 may be spaced apart from the upper surface of the active pattern AP in the vertical direction the third direction DR3 with the first channel pattern CH1 in between. The pair of second source/drain patterns SD2 may overlap with the first source/drain patterns SD1 in the vertical direction the third direction DR3. The second source/drain patterns SD2 may be spaced apart from the active pattern AP in the vertical direction the third direction DR3 with the first source/drain pattern SD1 in between. The second gate electrode GE2 may surround each of the corresponding semiconductor patterns S1 and S2 within the second channel pattern CH2.

In one or more embodiments, the first gate electrode GE1 and the second gate electrode GE2 that vertically overlap one another may be connected to form a single gate electrode GE.

A minimum separation distance between the first channel pattern CH1 and the second channel pattern CH2 in the vertical direction the third direction DR3 may be greater than a minimum separation distance between the plurality of first semiconductor patterns S1 and S2 included in the first channel pattern CH1. A minimum separation distance between the first channel pattern CH1 and the second channel pattern CH2 in the vertical direction the third direction DR3 may be greater than a minimum separation distance between the plurality of second semiconductor patterns S1 and S2 included in the second channel pattern CH2.

The first source/drain pattern SD1 and the second source/drain pattern SD2 may each include an epitaxially grown semiconductor layer.

In one or more embodiments, one of the first and second transistors TR1 and TR2 may be an N-type metal oxide semiconductor NMOS field-effect transistor, and the other of the first and second transistors TR1 and TR2 may be a P-type metal oxide semiconductor PMOS field-effect transistor. In example embodiments, the first transistor TR1 may be a PMOS field-effect transistor. In example embodiments, the second transistor TR2 may be an NMOS field-effect transistor.

A contact may be connected to at least one of the first and second source/drain patterns SD1 and SD2 of the first and second transistors TR1 and TR2. The contact may extend in the vertical direction, for example, the third direction DR3, to be connected to at least one of the first and second source/drain patterns SD1 and SD2. In example embodiments, the contact may include a first contact CT1 connected to at least one of the first source/drain patterns SD1 of the first transistor TR1, and a second contact CT2 connected to at least one of the second source/drain patterns SD2 of the second transistor TR2. The contacts may have a bottle neck shape or a bottle neck structure with different diameters depending on their locations in the vertical direction. For example, the contact may have a smaller diameter at the second level than at a location other than the second level.

Hereinafter, a structure of a semiconductor device according to one or mor embodiments will be described in detail with reference to accompanying drawings.

A shallow trench isolation pattern STI may be provided on the substrate 100. The shallow trench isolation pattern STI may fill a trench TR. The shallow trench isolation pattern STI may include a silicon oxide. The shallow trench isolation pattern STI may not cover the active pattern AP.

A first channel pattern CH1 may be provided on the active pattern AP. The first channel pattern CH1 may include a stacked semiconductor pattern S1 and S2. The semiconductor patterns S1 and S2 may be spaced apart from one another. In one or more embodiments, the first channel pattern CH1 may include two first and second semiconductor patterns S1 and S2 that are vertically stacked and spaced apart from one another. However, the number of semiconductor patterns is not limited thereto, and may be provided in various numbers, for example, one, or three or more.

Each of the first and second semiconductor patterns S1 and S2 of the first channel pattern CH1 may include silicon (Si), germanium (Ge), or silicon-germanium (SiGe). For example, each of the first and second semiconductor patterns S1 and S2 of the first channel pattern CH1 may include single-crystal silicon.

A first gate electrode GE1 may be provided on the first and second semiconductor patterns S1 and S2 of the first channel pattern CH1. The first gate electrode GE1 may be vertically stacked with the first and second semiconductor patterns S1 and S2 of the first channel pattern CH1. For example, the first gate electrode GE1 may be alternately stacked with the first and second semiconductor patterns S1 and S2 of the first channel pattern CH1 in the third direction DR3. For example, the first gate electrode GE1 may be interposed between the first and second semiconductor patterns S1 and S2 of the first channel pattern CH1. The first gate electrode GE1 may be disposed over a topmost one of the first and second semiconductor patterns S1 and S2 of the first channel pattern CH1, and under a bottommost one of the first and second semiconductor patterns S1 and S2 of the first channel pattern CH1. Accordingly, the first gate electrode GE1 may vertically overlap the first channel pattern CH1.

The first gate electrode GE1 may surround the first channel pattern CH1. The first gate electrode GE1 may surround each of the first and second semiconductor patterns S1 and S2 of the first channel pattern CH1. For example, the first gate electrode GE1 may be provided on an upper surface, a lower surface, a front surface, and a rear surface of each of the first and second semiconductor patterns S1 and S2 of the first channel pattern CH1. Accordingly, a transistor according to these embodiments may be a three-dimensional field-effect transistor (for example, a multi-bridge channel field-effect transistor (MBCFET) or a gate-all-around field-effect transistor (GAAFET)) in which the first gate electrode GE1 is disposed to three-dimensionally surrounds the channel.

The first gate electrode GE1 may extend in a planar manner on the upper surface of the substrate 100. In one or more embodiments, the first gate electrode GE1 may be disposed between the substrate 100 and a lowermost pattern among the first and second semiconductor patterns S1 and S2 of the first channel pattern CH1, and may extend in the second direction DR2.

A gate insulating layer GI may be provided between the first gate electrode GE1 and the first and second semiconductor patterns S1 and S2 of the first channel pattern CH1. The gate insulating layer GI may be provided on the first and second semiconductor patterns S1 and S2 of the first channel pattern CH1. The gate insulating layer GI may surround each of the first and second semiconductor patterns S1 and S2 of the first channel pattern CH1. For example, the gate insulating layer GI may be provided on an upper surface, a lower surface, a front surface, and a rear surface of each of the first and second semiconductor patterns S1 and S2 of the first channel pattern CH1. The gate insulating layer GI may be in contact with the first and second semiconductor patterns S1 and S2.

The gate insulating layer GI may extend above the upper surface of the substrate 100 in plan view. The gate insulating layer GI may be in contact with the upper surface of the active pattern AP. The gate insulating layer GI may be disposed between the upper surface of the substrate 100 and the first gate electrode GE1.

The gate insulating layer GI may include an interfacial layer and a high-κ dielectric layer. The interfacial layer may include at least one of a silicon oxide and a silicon oxynitride. The high-κ dielectric layer may include a high-κ dielectric material having a higher dielectric constant than a silicon oxide. In one or more embodiments, the high-κ dielectric layer may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

Although not illustrated, a diffusion barrier pattern may be provided on the gate insulating layer GI that surrounds each of the first and second semiconductor patterns S1 and S2. The diffusion barrier pattern may be disposed between the gate insulating layer GI and the first gate electrode GE1. The diffusion barrier pattern may reduce the exchange of materials between the first gate electrode GE1 and the gate insulating layer GI. For example, the diffusion barrier pattern may significantly reduce the diffusion of metal elements included in the first gate electrode GE1 into the gate insulating layer GI.

A first source/drain pattern SD1 may be provided on at least one side of the first channel pattern CH1. The first source/drain pattern SD1 may be provided on opposite sides of the first channel pattern CH1, and the first channel pattern CH1 may connect the first source/drain patterns SD1 on opposite sides. For example, the first and second semiconductor patterns S1 and S2 may be connected to the first source/drain patterns SD1 disposed on the opposite sides thereof.

Although not illustrated, a seed pattern may be provided beneath the first source/drain pattern SD1. The seed pattern may be provided in a second recess RC2 defined between the active patterns AP. The second recess RC2 may be formed in a depth direction from the upper surface of the substrate 100. The first source/drain pattern SD1 may be formed by a selective epitaxial growth process from the seed pattern.

A second channel pattern CH2 may be provided on the first channel pattern CH1. The second channel pattern CH2 may include a sequentially stacked first and a second semiconductor pattern S1 and S2. The first and second semiconductor patterns S1 and S2 may be spaced apart from one another. In one or more embodiments, the second channel pattern CH2 may include two first and second semiconductor patterns S1 and S2 that are vertically stacked and spaced apart from one another. However, the number of semiconductor patterns of the second channel pattern CH2 is not limited thereto, and semiconductor patterns of the second channel pattern CH2 may be provided in various numbers, for example, one, or three or more.

The first and second semiconductor patterns S1 and S2 of the second channel pattern CH2 may be located at a higher level than the first and second semiconductor patterns S1 and S2 of the first channel pattern CH1. The number of semiconductor patterns of the second channel pattern CH2 may be the same as or different from the number of semiconductor patterns of the first channel pattern CH1.

Each of the first and second semiconductor patterns S1 and S2 of the second channel pattern CH2 may include silicon (Si), germanium (Ge), or silicon-germanium (SiGe). The first and second semiconductor patterns S1 and S2 of the second channel pattern CH2 may be formed of the same material as the first and second semiconductor patterns S1 and S2 of the first channel pattern CH1. For example, each of the first and second semiconductor patterns S1 and S2 of the second channel pattern CH2 may include single-crystal silicon.

A second gate electrode GE2 may be provided on the first and second semiconductor patterns S1 and S2 of the second channel pattern CH2. The second gate electrode GE2 may be vertically stacked with the first and second semiconductor patterns S1 and S2 of the second channel pattern CH2. For example, the second gate electrode GE2 may be alternately stacked with the first and second semiconductor patterns S1 and S2 of the second channel pattern CH2 in the third direction DR3. For example, the second gate electrode GE2 may be interposed between the first and second semiconductor patterns S1 and S2 of the second channel pattern CH2. The second gate electrode GE2 may also be disposed over an uppermost semiconductor pattern among the first and second semiconductor patterns S1 and S2 and under a lowermost semiconductor pattern among the first and second semiconductor patterns S1 and S2. Accordingly, the second gate electrode GE2 may vertically overlap the second channel pattern CH2.

The second gate electrode GE2 may surround the second channel pattern CH2. The second gate electrode GE2 may surround each of the first and second semiconductor patterns S1 and S2. For example, the second gate electrode GE2 may be provided on an upper surface, a lower surface, a front surface, and a rear surface of each of the first and second semiconductor patterns S1 and S2. Accordingly, a transistor according to these embodiments may be a three-dimensional field-effect transistor (for example, an MBCFET or a GAAFET) in which the second gate electrode GE2 is disposed to three-dimensionally surrounds the channel.

The gate electrode GE may be formed of a metal, a metal nitride, a metal carbide, or combinations thereof. The metal may be selected from Ti, W, Ru, Nb, Mo, Hf, Ni, Co, Pt, Yb, Tb, Dy, Er, or Pd. The metal nitride may be selected from TiN or TaN. The metal carbide may be TiAIC. However, a material forming the gate electrode GE is not limited to the above-mentioned examples.

The second gate electrode GE2 may be formed integrally with the first gate electrode GE1 without separation to be connected to one another. However, the first and second gate electrodes GE1 and GE2 may be formed separately. When the first and second gate electrodes GE1 and GE2 are formed separately, at least one of the two gate electrodes GE may extend in the third direction DR3, so that the first and second gate electrodes GE1 and GE2 may be connected to one another.

A gate insulating layer GI may be provided between the second gate electrode GE2 and the first and second semiconductor patterns S1 and S2 of the second channel pattern CH2. The gate insulating layer GI may be provided on the first and second semiconductor patterns S1 and S2 of the second channel pattern CH2. The gate insulating layer GI may surround each of the first and second semiconductor patterns S1 and S2 of the second channel pattern CH2. For example, the gate insulating layer GI may be provided on an upper surface, a lower surface, a front surface, and a rear surface of each of the first and second semiconductor patterns S1 and S2 of the second channel pattern CH2. The gate insulating layer GI may be in contact with the first and second semiconductor patterns S1 and S2 of the second channel pattern CH2.

Although not illustrated, a diffusion barrier pattern may also be provided on the gate insulating layer GI surrounding each of the first and second semiconductor patterns S1 and S2 of the second channel pattern CH2. The diffusion barrier pattern may also be disposed between the gate insulating layer GI and the second gate electrode GE2. For example, the diffusion barrier pattern may separate the gate insulating layer GI and the second gate electrode GE2. Accordingly, the gate insulating layer GI may not be in direct contact with the second gate electrode GE2.

In example embodiments, the first and second semiconductor patterns S1 and S2 of the first channel pattern CH1 and the first and second semiconductor patterns S1 and S2 of the second channel pattern CH2 may be formed of a semiconductor layer having the same element. In one example, the first and second semiconductor patterns S1 and S2 of the first and second channel patterns CH1 and CH2 may each be formed of a Si layer. In example embodiments, the first and second semiconductor patterns S1 and S2 of the first and second channel patterns CH1 and CH2 may each be formed of an undoped Si layer. In example embodiments, the first and second semiconductor patterns S1 and S2 of the first channel pattern CH1 may each be formed of a silicon (Si) layer doped with an impurity of the same conductivity type as the conductivity type of the first source/drain pattern SD1, and the first and second semiconductor patterns S1 and S2 of the second channel pattern CH2 may be formed of a silicon (Si) layer doped with an impurity of the same conductivity type as the conductivity type of the second source/drain pattern SD2. In example embodiments, the first and second semiconductor patterns S1 and S2 of the first channel pattern CH1 may be formed of a silicon (Si) layer doped with an impurity of a conductivity type opposite to the conductivity type of the first source/drain pattern SD1, and the first and second semiconductor patterns S1 and S2 of the second channel pattern CH2 may be formed of a silicon (Si) layer doped with an impurity of a conductivity type opposite to the conductivity type of the second source/drain pattern SD2.

A pair of gate spacers GS may be provided on the second channel pattern CH2. The gate spacers GS may extend in the third direction DR3. The pair of gate spacers GS may be spaced apart from one another. The gate spacers GS may include at least one of SiCN, SiCON, or SiN. Alternatively, the gate spacers GS may have a multilayer structure formed of at least two of SiCN, SiCON, or SiN.

A gate capping pattern 160 may be provided between the pair of gate spacers GS. The gate capping pattern 160 may fill a space between the pair of gate spacers GS. The gate capping pattern 160 may be disposed on the second channel pattern CH2. The gate capping pattern 160 may be disposed on the gate electrode GE.

The gate capping pattern 160 may include a material that has an etching selectivity with respect to the first and second interlayer insulating layers 140 and 170 to be described later. For example, the gate capping pattern 160 may include at least one of SiON, SiCN, SiCON, or SiN.

A second source/drain pattern SD2 may be provided on at least one side of the second channel pattern CH2. The second source/drain pattern SD2 may be provided on opposite sides of the second channel pattern CH2, and the second channel pattern CH2 may connect the second source/drain patterns SD2 on opposite sides to one another. For example, the first and second semiconductor patterns S1 and S2 may be connected to the second source/drain patterns SD2 located on their opposite sides.

The first source/drain pattern SD1 and the second source/drain pattern SD2 may each be formed of an epitaxially grown semiconductor layer. In example embodiments, the first source/drain pattern SD1 and the second source/drain pattern SD2 may each be formed of a group IV element semiconductor, a group IV-IV compound semiconductor, or combinations thereof.

One of the first and second transistors TR1 and TR2 may be an NMOS transistor, and the other of the first and second transistors TR1 and TR2 may be a PMOS transistor. Therefore, the first source/drain pattern SD1 and the second source/drain pattern SD2 may be doped with different conductivity types depending on the types of the first and second transistors TR1 and TR2. For example, the first source/drain pattern SD1 may be a first conductivity type impurity region, and the second source/drain pattern SD2 may be a second conductivity type impurity region. For example, the first source/drain pattern SD1 may be a P-type impurity region, and the second source/drain pattern SD2 may be an N-type impurity region. Conversely, the first source/drain pattern SD1 may be an N-type impurity region, and the second source/drain pattern SD2 may be a P-type impurity region. The P-type impurity may be selected from boron (B) and gallium (Ga). The N-type impurity may be selected from phosphorus (P), arsenic (As), and antimony (Sb).

In one or more embodiments, the first source/drain pattern SD1 may include the same semiconductor element as the substrate 100. The second source/drain pattern SD2 may include a semiconductor element (for example, SiGe) having a larger lattice constant than the semiconductor element of the substrate 100. Accordingly, the pair of second source/drain patterns SD2 may provide a compressive stress to the second channel pattern CH2 therebetween.

Each first source/drain pattern SD1 may include a first and a second epitaxial layer SD1a, and SD1b having different impurity concentrations. For example, the second epitaxial layer SD1b may have a higher impurity concentration than the first epitaxial layer SD1a.

For example, when the first transistor TR1 is a PMOS transistor, the first source/drain pattern SD1 may include silicon germanium SiGe, and a germanium Ge concentration of the second epitaxial layer SD1b may be higher than a germanium Ge concentration of the first epitaxial layer SD1a. For example, the germanium Ge concentration of the first epitaxial layer SD1a may be in a range of about 1 at % to about 15 at %, and the germanium (Ge) concentration of the second epitaxial layer SD1b may be in a range of about 20 at % to about 100 at %. Also, the second epitaxial layer SD1b may have a higher doping concentration of dopants, for example, impurities, than the first epitaxial layer SD1a. The impurities may be at least one of boron (B), gallium (Ga), or indium (In).

Each second source/drain pattern SD2 may also include a first and a second epitaxial layer SD2a and SD2b having different impurity concentrations. The second epitaxial layer SD2b of each second source/drain pattern SD2 may have a higher impurity concentration than the first epitaxial layer SD2a. For example, when the first transistor TR1 is an NMOS transistor, a germanium (Ge) concentration of the second epitaxial layer SD2b may be higher than a germanium (Ge) concentration of the first epitaxial layer SD2a. For example, the germanium (Ge) concentration of the first epitaxial layer SD2a may be in a range of about 0 at % to about 15 at %, and the germanium (Ge) concentration of the second epitaxial layer SD2b may be in a range of about 20 at % to about 100 at%. Also, the second epitaxial layer SD2b may have a higher doping concentration of dopants, for example, impurities, than the first epitaxial layer SD2a. The impurities may be at least one of phosphorus (P), arsenic (As), or antimony (Sb).

A first interlayer insulating layer 140 may be provided on the substrate 100. The first interlayer insulating layer 140 may cover the second source/drain pattern SD2. An upper surface of the first interlayer insulating layer 140 may be substantially coplanar with upper surfaces of the gate capping pattern 160 and the gate spacers GS.

A protective insulating pattern 150 may be provided on the first interlayer insulating layer 140. The protective insulating pattern 150 may protect the first interlayer insulating layer 140 and the second source/drain pattern SD2 disposed therebelow.

A second interlayer insulating layer 170 may be provided on the first interlayer insulating layer 140 to cover the gate capping pattern 160. The second interlayer insulating layer 170 may be provided on the protective insulating pattern 150. The second interlayer insulating layer 170 may cover the gate spacer GS and the protective insulating pattern 150. In one or more embodiments, the first and second interlayer insulating layers 170 may include a silicon oxide. The protective insulating pattern 150 may include a silicon nitride layer.

An intermediate isolation pattern 130 may be provided between the first channel pattern CH1 and the second channel pattern CH2. The first channel pattern CH1, the intermediate isolation pattern 130, and the second channel pattern CH2 may form a stacked structure. The first channel pattern CH1, the intermediate isolation pattern 130, and the second channel pattern CH2 may be sequentially stacked.

The intermediate isolation pattern 130 may separate the stacked first channel pattern CH1 and second channel pattern CH2.

A gate insulating layer GI may also be provided on the intermediate isolation pattern 130. The gate insulating layer GI may surround the intermediate isolation pattern 130. For example, the gate insulating layer GI may be provided on an upper surface, a lower surface, a front surface, and a rear surface of the intermediate isolation pattern 130. The gate insulating layer GI may be in contact with the intermediate isolation pattern 130.

The first gate electrode GE1 on the first channel pattern CH1 may extend onto the intermediate isolation pattern 130. The second gate electrode GE2 on the second channel pattern CH2 may extend onto the intermediate isolation pattern 130. The first gate electrode GE1 and the second gate electrode GE2 may be connected on the intermediate isolation pattern 130.

An additional isolation pattern 135 may be provided on one side of the intermediate isolation pattern 130. The additional isolation pattern 135 may be provided on opposite sides of the intermediate isolation pattern 130.

The additional isolation pattern 135 may be disposed between the first source/drain pattern SD1 and the second source/drain pattern SD2. For example, the additional isolation pattern 135 may be disposed on the first source/drain pattern SD1. The additional isolation pattern 135 may be disposed beneath the second source/drain pattern SD2. For example, the first source/drain pattern SD1, the additional isolation pattern 135, and the second source/drain pattern SD2 may be sequentially stacked. An upper surface of the additional isolation pattern 135 may be in contact with a lower surface of the second source/drain pattern SD2.

The first interlayer insulating layer 140 may be stacked on the additional isolation pattern 135. The first interlayer insulating layer 140 may surround the second source/drain pattern SD2. For example, a lower surface of the first interlayer insulating layer 140 may be substantially coplanar with the lower surface of the second source/drain pattern SD2. An upper surface of the first interlayer insulating layer 140 may be disposed above the second source/drain pattern SD2.

Contacts for electrical connection with other components may be provided in the first and/or second source/drain patterns SD1 and SD2.

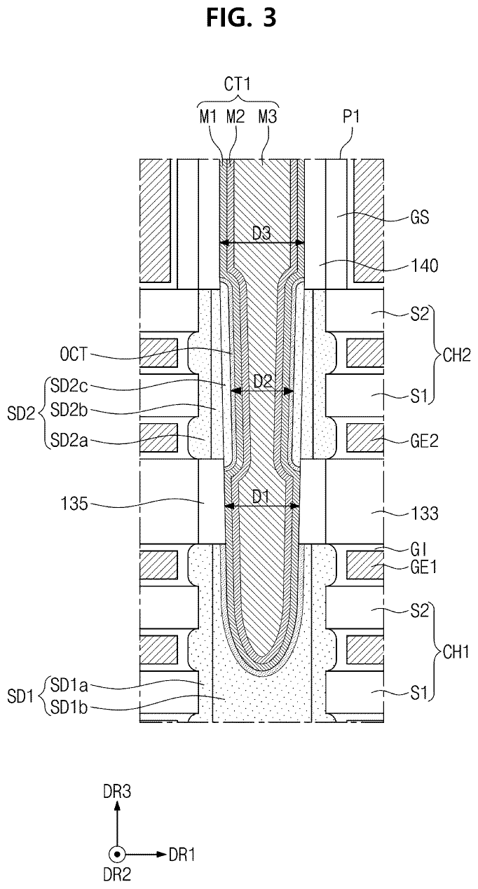

FIG. 3 is a part of a cross-sectional view illustrating a single contact, and is an enlarged cross-sectional view of the portion P1 of FIG. 2A.

Referring to FIG. 3, the contacts may include a first contact CT1 that vertically connects at least one of the first source/drain patterns SD1 and a second contact CT2 that vertically connects at least one of the second source/drain patterns SD2.

The first contact CT1 may be formed in a third recess RC3. The third recess RC3 may be provided in the first and second source/drain patterns SD1 and SD2 that are vertically stacked on the active pattern AP. The third recess RC3 may vertically penetrate through the second source/drain pattern SD2 and the additional isolation pattern 135, and may have a shape recessed vertically downward from the upper surface of the first source/drain pattern SD1. For example, the third recess RC3 may vertically penetrate through the second interlayer insulating layer 170, the protective insulating pattern 150, the gate capping pattern 160, the second source/drain pattern SD2, and the additional isolation pattern 135, and may have a shape recessed vertically downward from the upper surface of the first source/drain pattern SD1.

The first contact CT1 may be formed of a single conductive material, but embodiments are not limited thereto. The first contact CT1 may include a plurality of conductive materials. The conductive material may include a metal and/or a metal nitride. The metal may be selected from Ti, W, Ru, Nb, Mo, Hf, Ni, Co, Pt, Yb, Tb, Dy, Er, or Pd. The metal nitride may be selected from TiN or TaN.

Also, the first contact CT1 may be formed as a multilayer structure. In one or more embodiments, the first contact CT1 may include two conductive layers. One of the two conductive layers may be a barrier layer, and the other may be a contact plug disposed on the barrier layer. The first contact CT1 may include, for example, first to third conductive layer M1, M2, and M3. At least one of the first to third conductive layers M1, M2, and M3 may include a material different from a remaining layer. In one or more embodiments, the first conductive layer M1 may include titanium, the second conductive layer M2 may include titanium nitride, and the third conductive layer M3 may include cobalt.

The third recess RC3 may have different diameters in the vertical direction. Hereinafter, the term “diameter” of a certain component refers to a distance between opposite ends of the component based on a direction parallel to a substrate surface of the substrate 100, for example, the first direction DR1. The “diameter” of an empty space such as a recess refers to a distance between opposing surfaces exposed by the empty space (for example, recess surfaces) based on a direction parallel to the substrate surface of the substrate 100, for example, the first direction DR1.

A third epitaxial layer SD2c may be provided in the second source/drain pattern SD2 to protrude toward the third recess RC3. The third epitaxial layer SD2c may be epitaxially grown from the second source/drain pattern SD2 along the horizontal direction.

The third epitaxial layer SD2c may contain a relatively high concentration of germanium. For example, a germanium concentration of the third epitaxial layer SD2c may be from about 20 at % to about 100 at %, for example, from about 30 at% to about 70 at%. In one or more embodiments of the present invention, an N-type impurity may be highly doped into the patterns of the third epitaxial layer SD2c. For example, the N-type impurity may be phosphorus, arsenic, or antimony.

An impurity concentration of the third epitaxial layer SD2c may be higher than an impurity concentration of the first and/or second epitaxial layer SD2a and SD2b. Alternatively, the impurity concentration of the third epitaxial layer SD2c may be substantially the same as the impurity concentration of the second epitaxial layer SD2b.

Due to the formation of the third epitaxial layer SD2c, the third recess RC3 may have a different diameter depending on the vertical position, and in particular, the third recess RC3 may have a bottle neck shape. In detail, a diameter of the third recess RC3 may have a different value depending on a vertical level in an upward direction from the substrate 100. When a diameter of the third recess RC3 at a point on the first source/drain pattern SD1 is a first diameter D1, and a diameter of the third recess RC3 at a point on the second source/drain pattern SD2 is a second diameter D2, the second diameter D2 may be smaller than the first diameter D1. Also, when a diameter of the third recess RC3 at a point on the first interlayer insulating layer 140 is a third diameter D3, the second diameter D2 may be smaller than the third diameter D3. The first diameter D1, the second diameter D2, and the third diameter D3 of the third recess RC3 may refer to a width of the first contact CT1 in the second direction DR2.

An ohmic contact layer OCT may be selectively provided between the first source/drain pattern SD1 and the first contact CT1, and between the second source/drain pattern SD2 and the first contact CT1. The ohmic contact layer OCT is provided to have a low contact resistance between the first contact CT1 and the first and/or second source/drain patterns SD1 and SD2. The ohmic contact layer OCT may include a metal silicide. In one or more embodiments, the metal silicide may be formed of a material such as CoSi, NiSi, TiSi, NiPtSi, or NiTiSi.

Returning to FIG. 2A, the first contact CT1 may be provided in a fourth recess RC4.

The fourth recess RC4 may have a shape recessed vertically downward from an upper surface of the second source/drain pattern SD2. For example, the fourth recess RC4 may penetrate through the second interlayer insulating layer 170, the protective insulating pattern 150, and the gate capping pattern 160, and may have a shape recessed vertically downward from the upper surface of the second source/drain pattern SD2.

The second contact CT2 may be formed of a single conductive material, but example embodiments are not limited thereto. The second contact CT2 may include a plurality of conductive materials. The conductive material may include a metal and/or a metal nitride. The metal may be selected from Ti, W, Ru, Nb, Mo, Hf, Ni, Co, Pt, Yb, Tb, Dy, Er, or Pd. The metal nitride may be selected from TiN or TaN.

Also, the second contact CT2 may be formed as a multi-layer. In one or more embodiments, the second contact CT2 may include two conductive layers. Alternatively, the second contact CT2 may include the first to third conductive layers M1, M2, and M3. At least one of the first to third conductive layers M1, M2, and M3 may include a material different from a remaining layer. In one or more embodiments, the first conductive layer M1 may include titanium, the second conductive layer M2 may include titanium nitride, and the third conductive layer M3 may include cobalt.

An ohmic contact layer OCT may be selectively provided between the second source/drain pattern SD2 and the second contact CT2. The ohmic contact layer OCT may be provided to have a low contact resistance between the first contact CT1 and the first and/or second source/drain patterns SD1 and SD2. The ohmic contact layer OCT may include a metal silicide. In one or more embodiments, the metal silicide may be formed of a material such as CoSi, NiSi, TiSi, NiPtSi, or NiTiSi.

A semiconductor device according to one or more embodiments may include the first transistor TR1 and the second transistor TR2 which are disposed to overlap one another in the vertical direction (the third direction DR3) on the active pattern AP, and the first transistor TR1 and the second transistor TR2 may have channel types of opposite conductivity types. When an area of the semiconductor device is reduced due to downscaling, the first transistor TR1 and the second transistor TR2 having channel types of opposite conductivity types may be stacked in a direction perpendicular to the upper surface of the substrate 100. Thus, the number of transistors per unit area may be further increased to improve the integration of the semiconductor device.

In a semiconductor device according to one or more embodiments, when a contact is connected to the second source/drain pattern SD2 of the second transistor TR2, a relatively high concentration of impurity-containing third epitaxial layer SD2c may be disposed to reduce a contact resistance between the first contact CT1 and the second source/drain pattern SD2.

When the third epitaxial layer SD2c is not provided, the second epitaxial layer SD2b in the second source/drain pattern SD2 may be excessively removed due to the formation of the third recess RC3 during a manufacturing process. Accordingly, only a small amount of the second epitaxial layer SD2b may remain in the second source/drain pattern SD2. Alternatively, the second epitaxial layer SD2b may be substantially all removed, so that only the first epitaxial layer SD2a may remain. When only a small amount of the second epitaxial layer SD2b remains or only the first epitaxial layer SD2a remains in the third recess RC3, the contact resistance between the second source/drain pattern SD2 and the first contact CT1 in the third recess RC3 may increase. In one or more embodiments, a heavily-doped third epitaxial layer SD2c may be provided in the second source/drain pattern SD2 to reduce a contact resistance between the first contact CT1 and the second source/drain pattern SD2.

Various modifications may be made within the scope without departing from the inventive concepts. In the above-described embodiments, the third epitaxial layer SD2c corresponding to the second contact CT2 is not formed in the second source/drain pattern SD2, but embodiments are not limited thereto. In example embodiments, the third epitaxial layer SD2c may also be formed in the second source/drain pattern SD2 corresponding to the second contact CT2.

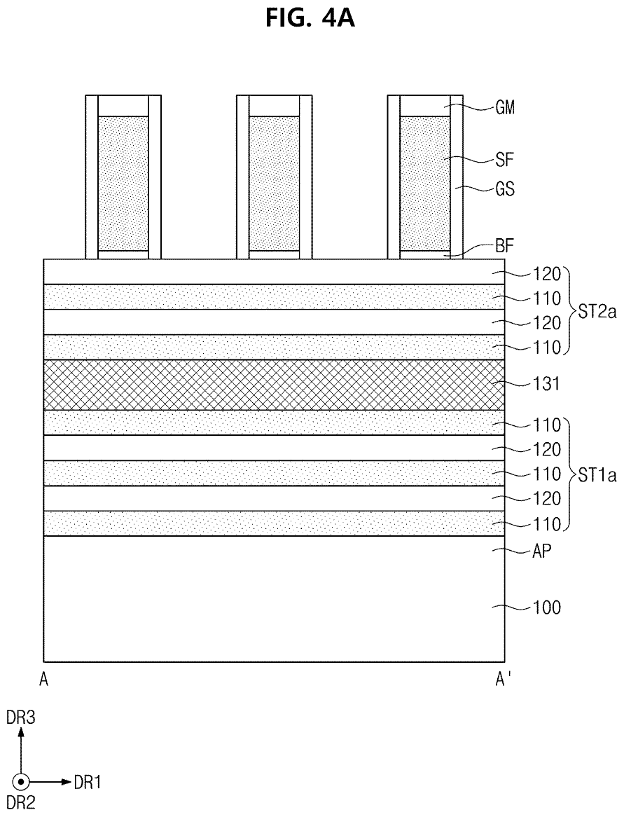

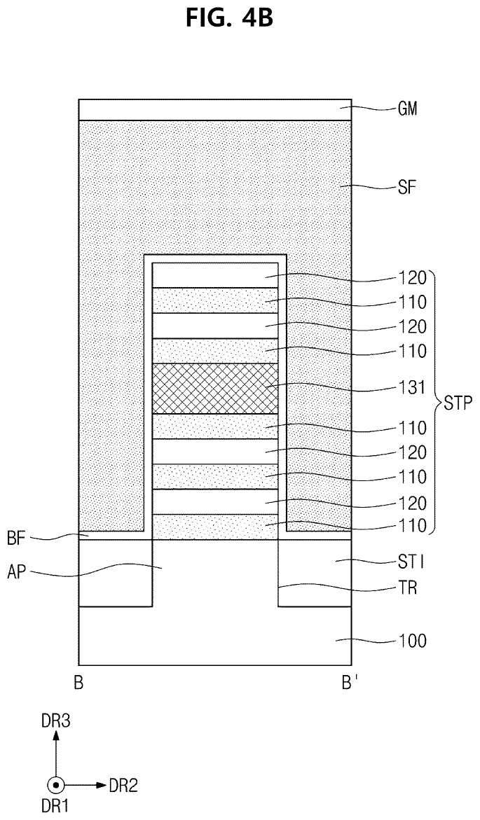

FIGS. 4A to 21 are views, sequentially illustrating a method of manufacturing a semiconductor device according to one or more embodiments. FIGS. 4A, 5A, 6 TO 10, 11A, 12A, 13A, 14A, and 15 to 21 are cross-sectional views taken along line A-A′ of FIG. 1, and FIGS. 4B, 5B, 11B, 12B, 13B, and 14B are cross-sectional views taken along line B-B′ of FIG. 1.

Referring to FIGS. 4A and 4B, a first preliminary stacked pattern ST1a, an intermediate semiconductor pattern 131, and a second preliminary stacked pattern ST2a may be sequentially formed on the substrate 100. The first and second preliminary stacked patterns ST1a and ST2a may include different material layers alternately arranged to facilitate the formation of the first and second channel patterns CH1 and CH2.

A first preliminary stacked pattern ST1a may be formed on the substrate 100. The first preliminary stacked pattern ST1a may include first semiconductor layers 110 and second semiconductor layers 120 that are alternately stacked. The first semiconductor layers 110 and the second semiconductor layers 120 may have different compositions. The first semiconductor layers 110 and the second semiconductor layers 120 may provide different etch selectivity and/or different oxidation rates.

In one or more embodiments, the first preliminary stacked pattern ST1a may include three layers of the first semiconductor layers 110 and two layers of the second semiconductor layers 120. However, the number of semiconductor layers included in the first preliminary stacked pattern ST1a is not limited thereto. In one or more embodiments, more or fewer semiconductor layers may be included in the first preliminary stacked pattern ST1a. For example, in some embodiments, the number of the first and second semiconductor layers 110 and 120 in the first preliminary stacked pattern ST1a may be 1 to 10.

The semiconductor layers 110 may include one of silicon (Si), germanium (Ge), or silicon-germanium (SiGe). The second semiconductor layers 120 may include materials other than the material forming the first semiconductor layers 110, for example, compound semiconductors such as Si, Ge, SiC, GeAs, GaP, InP, InAs, and/or InSb, alloy semiconductors such as SiGe, GaAsP, AlInAs, AlGaAs, InGaAs, GaInP, and/or GaInAsP, or combinations thereof. In one or more embodiments, the first semiconductor layers 110 may include silicon-germanium (SiGe), and the second semiconductor layers 120 may include silicon (Si).

The first and second semiconductor layers 110, 120 may be formed by a molecular beam epitaxy (MBE) process, a metalorganic chemical vapor deposition (MOCVD) process, and/or another appropriate epitaxial growth process. A portion of the first and second semiconductor layers 110 and 120 may be removed in a subsequent process, and may serve to define a vertical distance between adjacent channel patterns for the semiconductor device to be finally formed. In one or more embodiments, a thickness of each of the first and second semiconductor layers 110 and 120 may vary according to embodiments.

An intermediate semiconductor pattern 131 may be formed on the first preliminary stacked pattern ST1a. For example, the intermediate semiconductor pattern 131 may be formed on an uppermost one of the alternately stacked first semiconductor layers 110 and second semiconductor layers 120 of the first preliminary stacked pattern ST1a. The intermediate semiconductor pattern 131 may include one of silicon (Si), germanium (Ge), and silicon-germanium (SiGe). In one or more embodiments, the intermediate semiconductor pattern 131 may be formed of the same material as the first semiconductor layers 110.

The intermediate semiconductor pattern 131 may have an etching selectivity with respect to the first semiconductor layer 110 and/or the second semiconductor layer 120. In one or more embodiments, a concentration of the silicon-germanium (SiGe) intermediate semiconductor pattern 131 may be higher than a concentration of the silicon-germanium (SiGe) first semiconductor layer 110. Accordingly, the intermediate semiconductor pattern 131 may have an etching selectivity with respect to the first semiconductor layer 110.

The second preliminary stacked pattern ST2a may be formed on the intermediate semiconductor pattern 131. The second preliminary stacked pattern ST2a may include alternately stacked first semiconductor layers 110 and second semiconductor layers 120. The first semiconductor layers 110 and the second semiconductor layers 120 may have different compositions. The first semiconductor layers 110 and the second semiconductor layers 120 may provide different etching selectivity and/or different oxidation rates.

The second preliminary stacked pattern ST2a may include two layers of the first semiconductor layers 110 and two layers of the second semiconductor layers 120. However, the number of the first and second semiconductor layers 110 and 120 included in the second preliminary stacked pattern ST2a is not limited thereto. In one or more embodiments, more or fewer semiconductor layers may be included in the second preliminary stacked pattern ST2a. For example, in some embodiments, the number of the first and second semiconductor layers 110 and 120 in the second preliminary stacked pattern ST2a may be 1 to 10.

The number of the first and second semiconductor layers 110 and 120 in the first preliminary stacked pattern ST1a and the number of the first and second semiconductor layers 110 and 120 in the second preliminary stacked pattern ST2a may be the same or different.

In one or more embodiments, the first semiconductor layers 110 in the first and second preliminary stacked patterns ST1a and ST2a may be formed of the same material, but embodiments are not limited thereto. The first semiconductor layers 110 in the first and second preliminary stacked patterns ST1a and ST2a may be formed of different materials. In addition, the second semiconductor layers 120 in the first and second preliminary stacked patterns ST1a and ST2a may be formed of the same material, but embodiments are not limited thereto. The second semiconductor layers 120 in the first and second preliminary stacked patterns ST1a and ST2a may be formed of different materials.

A mask pattern may be formed on the active pattern AP of the substrate 100. A patterning process of the stacked pattern and the substrate 100 may be performed using the mask pattern as an etching mask to form a trench TR that defines the active pattern AP. The trench TR may be formed on opposite sides of the active pattern AP.

The shallow trench isolation pattern STI may fill the trench TR. For example, an insulating layer covering the active pattern AP and the stacked pattern may be formed on the entire surface of the substrate 100. The insulating layer may be recessed until the stacked pattern is exposed to form the shallow trench isolation pattern STI. The shallow trench isolation pattern STI may be formed by a high density plasma chemical vapor deposition (HDP-CVD) process, a flowable CVD (FCVD) process, or another appropriate deposition process.

The shallow trench isolation pattern STI may include a silicon oxide, a silicon nitride, a silicon oxynitride, a fluorine-doped silicate glass FSG, a low-κ dielectric, or combinations thereof. In one or more embodiments, the shallow trench isolation pattern STI may include a silicon oxide. The stacked pattern may be exposed over the shallow trench isolation pattern STI. For example, the stacked pattern may vertically protrude upwardly of the shallow trench isolation pattern STI.

A sacrificial pattern SF may include various materials, for example, polysilicon. The sacrificial pattern SF may be replaced with a gate electrode GE of a semiconductor device in a subsequent process. Accordingly, a width of the sacrificial pattern SF may be substantially the same as a width of the gate electrode GE of the semiconductor device to be replaced later.

Forming the sacrificial pattern SF may include forming a sacrificial layer on the entire surface of the substrate 100, forming a mask pattern on the sacrificial layer, and patterning the sacrificial layer using the mask pattern as an etching mask.

The sacrificial layer may be deposited using CVD including low-pressure chemical vapor deposition (LPCVD) and plasma-enhanced chemical vapor deposition (PECVD), physical vapor deposition (PVD), atomic layer deposition (ALD), or another appropriate process. A portion of the sacrificial layer may be removed using plasma dry etching and/or wet etching. In some embodiments, when the sacrificial layer is polysilicon, wet etching may be performed to selectively remove a portion of the sacrificial layer, and various etchants such as a tetramethylammonium hydroxide (TMAH) solution may be used.

A pair of gate spacers GS may be formed on opposite sidewalls of each sacrificial pattern SF. Forming the gate spacers GS may include conformally forming a gate spacer layer on the upper surface of the substrate 100, and anisotropically etching the gate spacer layer. The gate spacer GS may include a material such as SiOₓ, SiCN, SiCON, SiN, or SiON. In another example, the gate spacer GS may have a multilayer structure including at least two of SiCN, SiCON, or SiN. A gate spacer (GS) layer may be formed using CVD including LPCVD and PECVD, PVD, ALD, or another appropriate process.

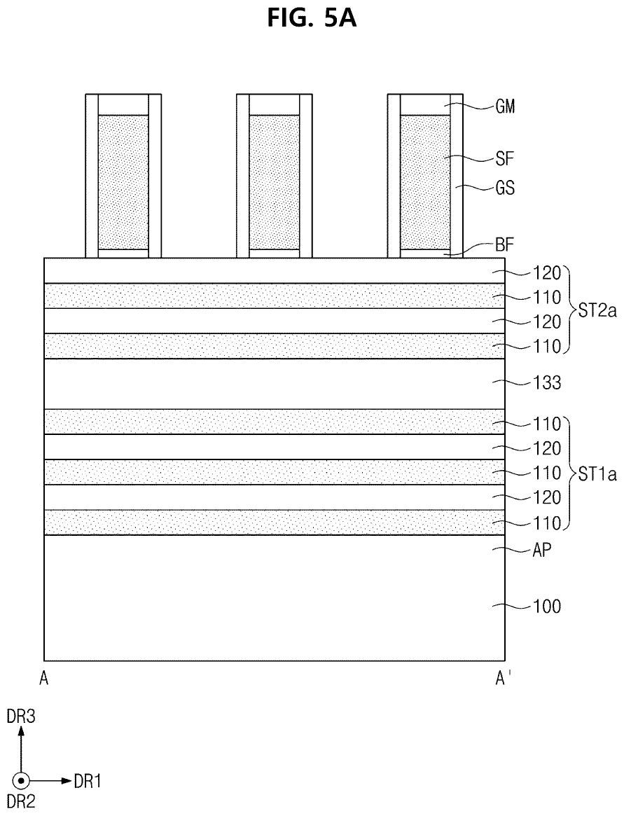

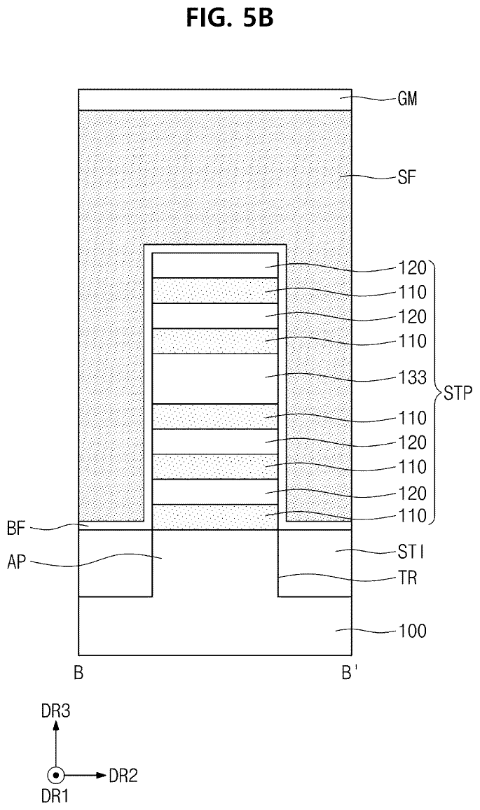

Referring to FIGS. 5A and 5B, a preliminary intermediate isolation pattern 133 may be formed between the first preliminary stacked pattern ST1a and the second preliminary stacked pattern ST2a. For example, forming the preliminary intermediate isolation pattern 133 may include removing the intermediate semiconductor pattern 131, and filling a space where the intermediate semiconductor pattern 131 was removed with the preliminary intermediate isolation pattern 133. In one or more embodiments, the preliminary intermediate isolation pattern 133 may include SiOCN.

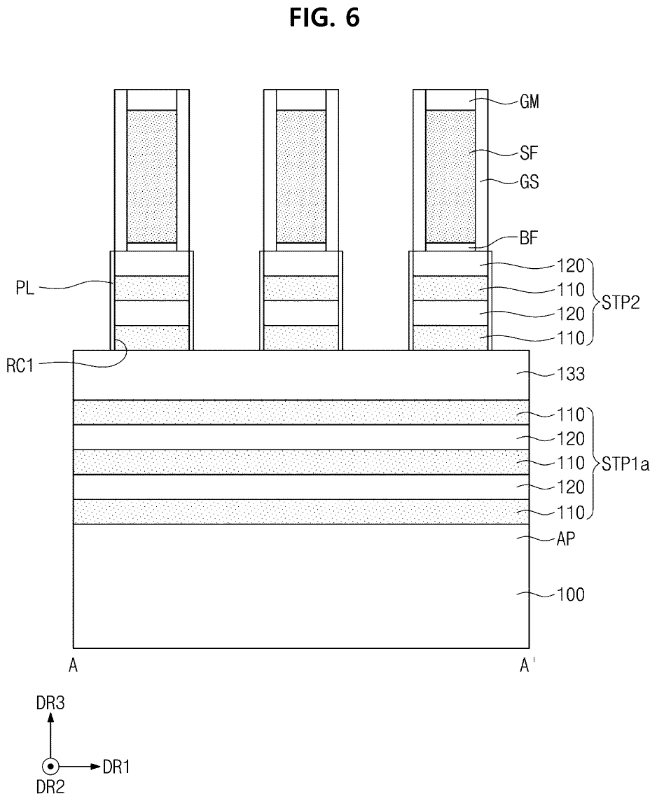

Referring to FIG. 6, first recesses RC1 may be formed in the second preliminary stacked pattern ST2a on the active pattern AP. For example, the first recesses RC1 may be formed by etching the second preliminary stacked pattern ST2a on the active pattern AP using gate masks GM and gate spacers GS as an etching mask. The first recesses RC1 may correspond to a region in which the second source/drain pattern SD2 is to be formed.

The first and second semiconductor patterns S1 and S2, stacked and spaced apart from one another, may be formed by the first recesses RC1. The first and second semiconductor layers 110 and 120 between the adjacent first recesses RC1 may form the second stacked pattern ST2.

A protective liner PL may be formed on an inner surface of the second stacked pattern ST2 that is exposed into the first recesses RC1.

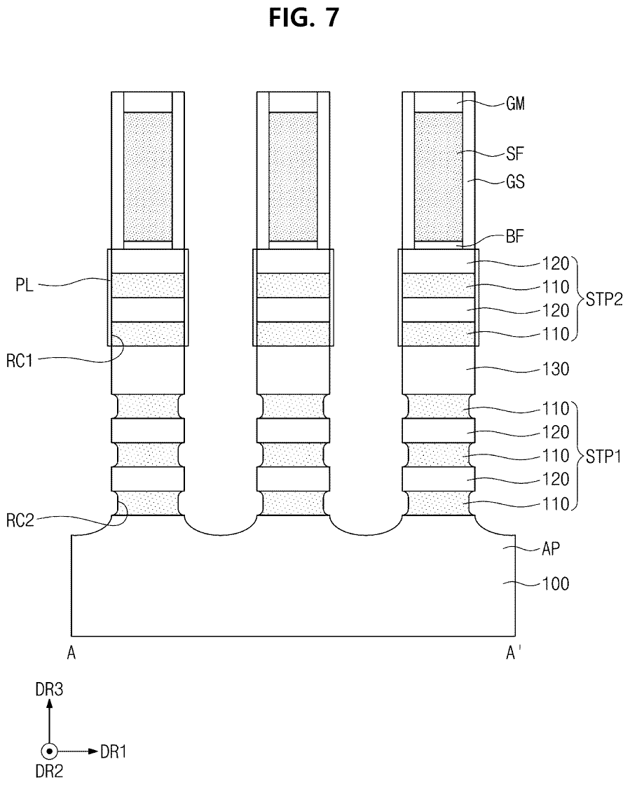

Referring to FIG. 7, second recesses RC2 may be formed in the preliminary intermediate isolation pattern 133 and the first preliminary stacked pattern ST1a on the active pattern AP. The second recesses RC2 may be formed corresponding to a region where the preliminary intermediate isolation pattern 133 and the second source/drain pattern SD2 will be formed. For example, the second recesses RC2 may be formed by sequentially etching the preliminary intermediate isolation pattern 133 and the first preliminary stacked pattern ST1a on the active pattern AP using the gate mask GM and the gate spacers GS as etching masks.

The first and second semiconductor patterns S1 and S2 and the preliminary intermediate isolation pattern 133, stacked and spaced apart from one another, may be formed by the second recesses RC2. The first and second semiconductor layers 110 and 120 between the adjacent first recesses RC1 may form the second stacked pattern ST2.

A portion of the first and second preliminary stacked patterns ST1a, ST2a may be removed by a suitable dry etching and/or wet etching process to remove the gate spacer GS and the first and second semiconductor layers 110 and 120 together or separately. The etching process may be anisotropically performed using the sacrificial pattern SF and the gate spacer GS provided on the stacked pattern as masks.

Although not illustrated, an additional recess may be formed beneath the second recesses RC2. The additional recess may be a location correspond to a seed pattern for forming the first source/drain pattern SD1.

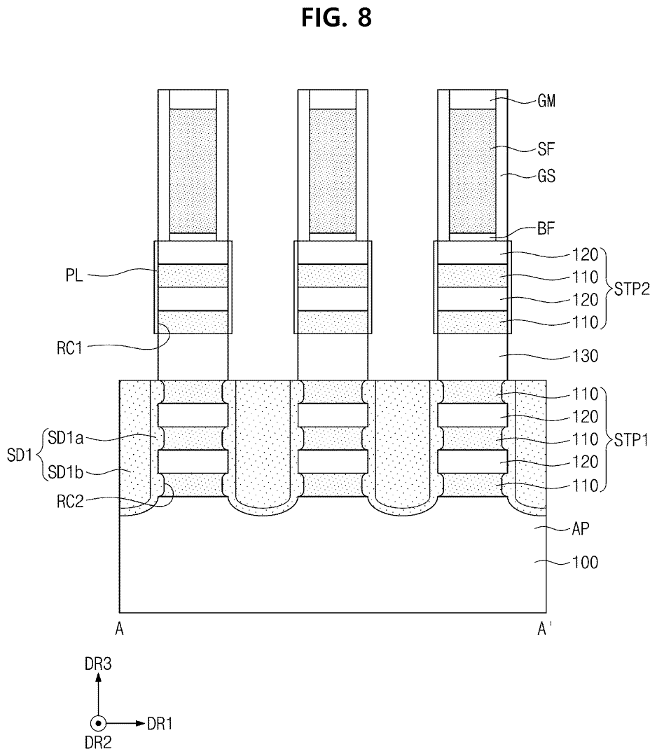

Referring to FIG. 8, first source/drain patterns SD1 may be formed in the second recesses RC2. The first source/drain patterns SD1 may be formed of an epitaxially grown semiconductor layer. The first source/drain patterns SD1 may be grown using the first and second semiconductor patterns S1 and S2, exposed by the second recesses RC2, as a seed. In one or more embodiments, a selective epitaxial growth process may include a chemical vapor deposition (CVD) process or a molecular beam epitaxy (MBE) process.

In one or more embodiments, the seed pattern may be formed in the additional recess. The seed pattern may fill the additional second recesses RC2. The seed pattern may include silicon (Si), germanium (Ge), or silicon-germanium (SiGe). A selective epitaxial growth process may be performed using the seed pattern as a seed layer to form an epitaxial layer filling the second recesses RC2.

The first source/drain patterns SD1 may be formed on opposite sides of the first stacked pattern ST1.

To form the first source/drain patterns SD1, a first selective epitaxial growth (SEG) process may be performed using inner walls of the second recesses RC2 as a seed layer to form a first epitaxial layer SD1a. The first epitaxial layer SD1amay be grown using the first and second semiconductor patterns S1 and S2 and the substrate 100 or the seed pattern, exposed by the first recesses RC1, as a seed. For example, the first SEG process may include a chemical vapor deposition (CVD) process or a molecular beam epitaxy (MBE) process.

The first epitaxial layer SD1a may include a semiconductor element (for example, SiGe) having a larger lattice constant than the semiconductor element of the substrate 100. The first epitaxial layer SD1a may contain a relatively low concentration of germanium. In one or more embodiments, the first epitaxial layer SD1a may contain only silicon Si excluding germanium. A concentration of germanium of the first epitaxial layer SD1a may be from 0 at % to 10 at %.

A second SEG process may be performed on the first epitaxial layer SD1a to form a second epitaxial layer SD1b. The second epitaxial layer SD1b may contain a relatively high concentration of germanium. For example, a concentration of germanium of the second epitaxial layer SD1b may be from 30 at % to 70 at %.

During the formation of the first epitaxial layer SD1a and the second epitaxial layer SD1b, impurities (for example, a P-type impurity such as boron, gallium, or indium) may be injected in-situ into the first source/drain patterns SD1. For example, impurities may be injected into the first source/drain patterns SD1 after the first source/drain patterns SD1 are formed.

Forming the first source/drain patterns SD1 may lead to formation of a first channel pattern CH1 between the two first source/drain patterns SD1. The first channel pattern CH1 may include the first and second semiconductor patterns S1 and S2 that are sequentially stacked.

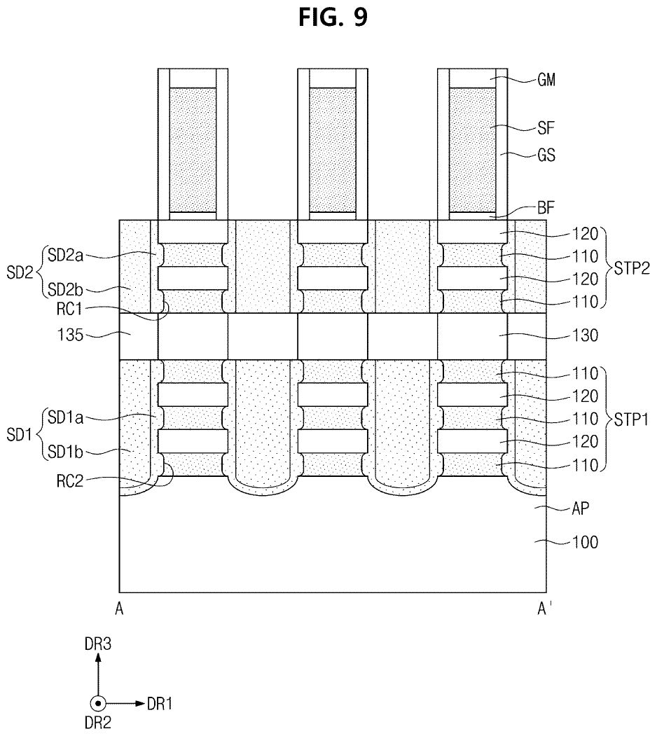

Referring to FIG. 9, an additional isolation pattern 135 may be formed on the first source/drain pattern SD1. For example, the additional isolation pattern 135 may be formed to surround the first source/drain pattern SD1. The additional isolation pattern 135 may fill the second recesses RC2 up to a height corresponding to an upper surface of the intermediate isolation pattern 130. The additional isolation pattern 135 may include a silicon oxide.

Second source/drain patterns SD2 may be formed on the additional isolation pattern 135. Before the second source/drain patterns SD2 are formed, the protective liner PL may be removed from the inner walls of the first recesses RC1.

The first source/drain pattern SD1 may be formed of an epitaxially grown semiconductor layer. The first source/drain pattern SD1 may be grown using the first and second semiconductor patterns S1 and S2 exposed by the second recess RC2 as a seed. In one or more embodiments, a selective epitaxial growth process may include a chemical vapor deposition (CVD) process or a molecular beam epitaxy (MBE) process.

In one or more embodiments, the second source/drain pattern SD2 may include the same semiconductor element (for example, Si) as the substrate 100. During the formation of the second source/drain pattern SD2, an impurity (for example, phosphorus, arsenic, or antimony) allowing the second source/drain pattern SD2 to have N-type may be injected in-situ. In one or more embodiments, impurities may also be injected into the second source/drain pattern SD2 after the formation of the second source/drain pattern SD2.

The second source/drain patterns SD2 may be formed on opposite sides of the second stacked pattern ST2.

To form the second source/drain patterns SD2, a first SEG process may be performed using inner walls of the first recesses RC1 as a seed layer to form a first epitaxial layer SD2a. The first epitaxial layer SD2a may be grown using the first and second semiconductor patterns S1 and S2 and the substrate 100 or the seed pattern exposed by the first recesses RC1 as a seed. For example, the first SEG process may include a chemical vapor deposition (CVD) process or a molecular beam epitaxy (MBE) process.

The first epitaxial layer SD2a may include a semiconductor element (for example, SiGe) having a larger lattice constant than the semiconductor element of the substrate 100. The first epitaxial layer SD2a may contain a relatively low concentration of germanium. In one or more embodiments, the first epitaxial layer SD2a may contain only silicon (Si) excluding (germanium). A concentration of germanium of the first epitaxial layer SD2a may be from 0 at% to 10 at %. A second SEG process may be performed on the first epitaxial layer SD2a to form a second epitaxial layer SD2b. The second epitaxial layer SD2b may contain a relatively high concentration of germanium (Ge). For example, a concentration of germanium of the second epitaxial layer SD2b may be from 30 at % to 70 at %.

During the formation of the first epitaxial layer SD2a and the second epitaxial layer SD2b, impurities (for example, an N-type impurity such as phosphorus, arsenic, or antimony) may be injected in-situ into the second source/drain patterns SD2. In another example, impurities may be injected into the first source/drain patterns SD1 after the second source/drain patterns SD2 are formed.

Forming the second source/drain patterns SD2 may lead to formation of a second channel pattern CH2 between the two second source/drain patterns SD2. The second channel pattern CH2 may include the first and second semiconductor patterns S1 and S2 that are sequentially stacked.

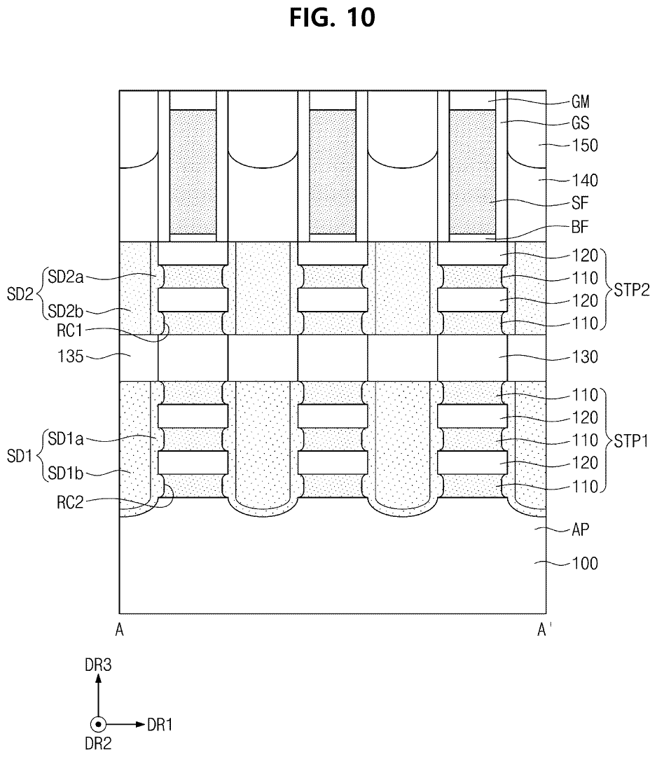

Referring to FIG. 10, a first interlayer insulating layer 140 may be formed on the second source/drain pattern SD2. For example, the first interlayer insulating layer 140 may be formed to surround the second source/drain pattern SD2. The first interlayer insulating layer 140 may include a silicon oxide.

The first interlayer insulating layer 140 may fill up to a height corresponding to an upper surface of the gate spacer GS and a height corresponding to an upper surface of the gate mask GM.

A protective insulating pattern 150 may be formed in the first interlayer insulating layer 140. For example, the first interlayer insulating layer 140 may be recessed, and the protective insulating pattern 150 may fill the recessed first interlayer insulating layer 140.

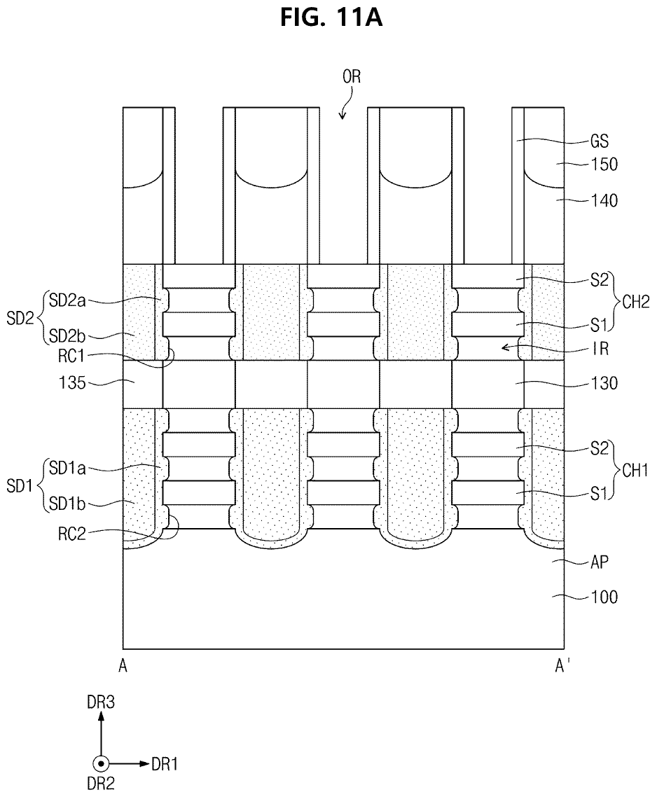

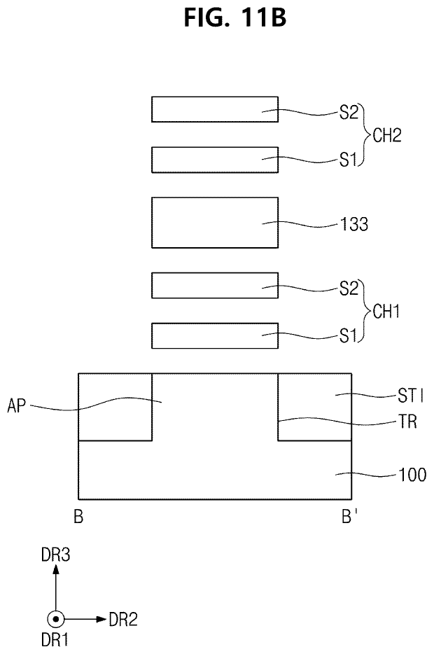

Referring to FIGS. 11a and 11b, the gate masks GM and the sacrificial patterns SF may then be selectively removed using photolithography. Removing the gate masks GM and the sacrificial patterns SF may lead to formation of an outer region OR exposing an uppermost surface of the second channel patterns. The sacrificial patterns SF may be removed by a wet etching process. In the wet etching process, for example, an etchant may be used to selectively etch polysilicon.

Then, the first semiconductor layers 110 exposed through the outer region OR may be selectively removed to form inner regions IR. The inner regions IR may be a region between the substrate 100 and the second semiconductor pattern S2, a region between the adjacent first and second semiconductor patterns S1 and S2 of the first stacked pattern ST1, a region between an uppermost second semiconductor pattern S2 of the first stacked pattern ST1 and the intermediate isolation pattern 130, a region between the intermediate isolation pattern 130 and a bottommost second semiconductor pattern S2 of the second stacked pattern ST2, and a region between the adjacent first and second semiconductor patterns S1 and S2 of the first stacked pattern ST1. For example, a selective etching process may be performed on the first semiconductor layers 110 to remove only the first and second semiconductor patterns S1 and S2 without removing the first and second semiconductor patterns S1 and S2. The etching process is based on the fact that a silicon-germanium with a relatively high germanium concentration may have a high etching rate with respect to a silicon-germanium with a low germanium concentration. For example, the etching process may have a high etching rate for a silicon-germanium with a germanium concentration greater than 10 at %. In one or more embodiments, the first semiconductor layers 110 may be selectively etched using a wet etchant that is not limited to an ammonium hydroxide (NH₄OH), tetramethylammonium hydroxide (TMAH), ethylenediamine pyrocatechol (EDP), or potassium hydroxide (KOH) solution.

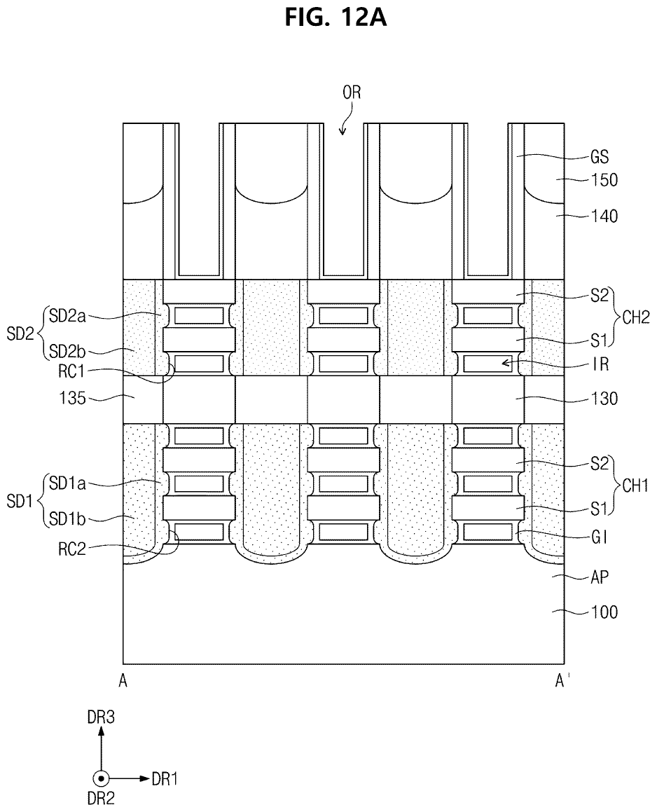

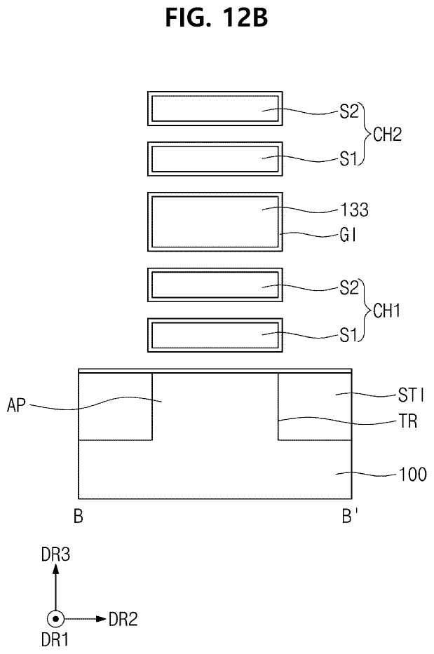

Referring to FIGS. 12A and 12B, a gate insulating layer GI may be conformally formed in the exposed inner region IR and the outer region OR on the active pattern AP.

The gate insulating layer GI may include an interfacial layer and a high-κ dielectric layer on the interfacial layer. In one or more embodiments, the high-κ dielectric layer may be thicker than the interfacial layer. The interfacial layer may include a silicon oxide or a silicon oxynitride layer. The high-κ dielectric layer may include a high-κ dielectric material having a higher dielectric constant than a silicon oxide. For example, the high-κ dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

The gate insulating layer GI may be formed using atomic layer deposition (ALD), chemical vapor deposition (CVD), or another appropriate method.

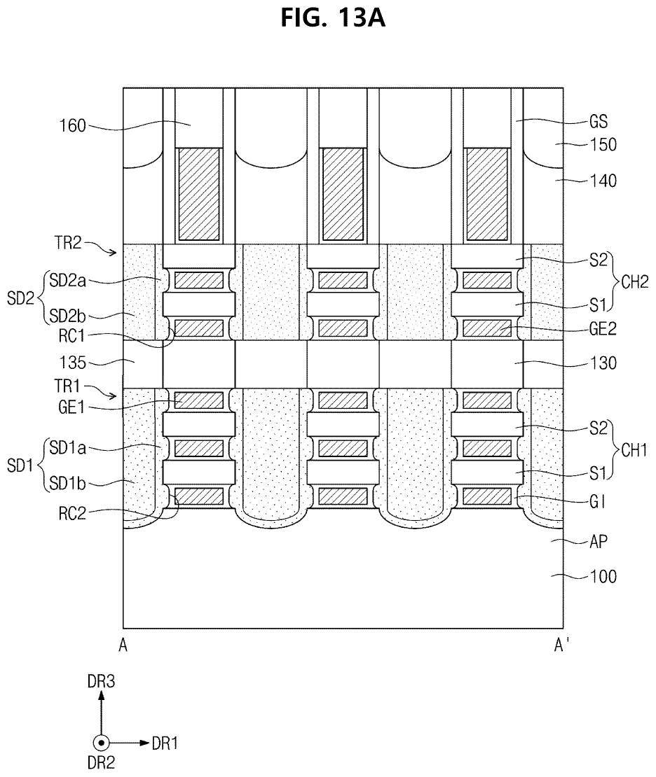

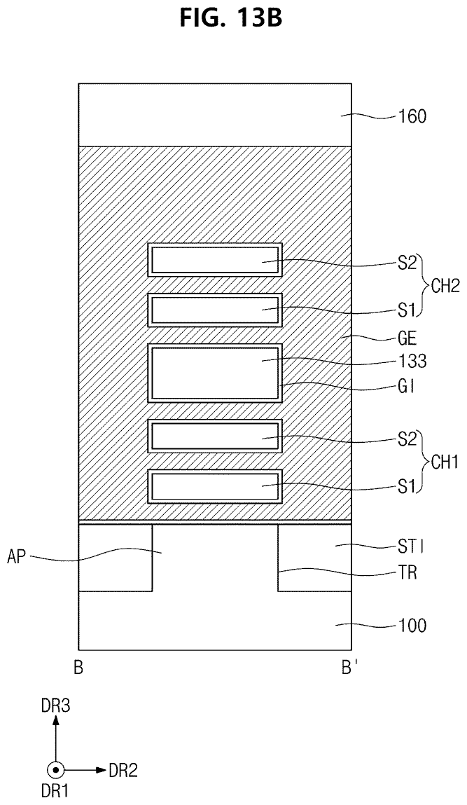

Referring to FIGS. 13A and 13B, a gate electrode GE may be formed on the gate insulating layer GI. The gate electrode GE may be formed to fill a portion of the outer region OR and the inner region IR. The gate electrode GE may include portions, respectively formed in the inner regions IR, and a portion formed in the outer region OR. The gate electrode GE may include a first gate electrode GE1 between the first source/drain patterns SD1 and a second gate electrode GE2 between the second source/drain patterns SD2, and the first and second gate electrodes GE1 and GE2 may be simultaneously formed in a single process. The first and second gate electrodes GE1 and GE2 may be formed integrally without separation thereof.

A gate capping pattern 160 may be formed on the gate. The gate capping pattern 160 may fill a space between the pair of gate spacers GS. An upper surface of the gate capping pattern 160 may be substantially coplanar with upper surfaces of the gate spacers GS and the protective insulating pattern 150. The gate capping pattern 160 may include SiN.

A second interlayer insulating layer 170 may be formed on the gate capping pattern 160. The second interlayer insulating layer 170 may cover the protective insulating pattern 150 and the gate spacer GS. The second interlayer insulating layer 170 may include a silicon oxide.

At least one contact for electrical connection to other components is formed in the first and/or second source/drain patterns SD1 and SD2. The contact may include a first contact CT1, vertically connecting at least one of the first source/drain patterns SD1, and a second contact CT2, vertically connecting at least one of the second source/drain patterns SD2. In one or more embodiments, the first contact CT1 may be formed first and then the second contact CT2 may be formed. However, embodiments are not limited thereto, and the second contact CT2 may be formed first and then the first contact CT1 may be formed. Alternatively, a portion of a process of forming the first contact CT1 and a portion of a process of forming the second contact CT2 may be simultaneously performed. Hereinafter, for clarity, an example is provided in which the first contact CT1 is formed, and the second contact CT2 is then formed.

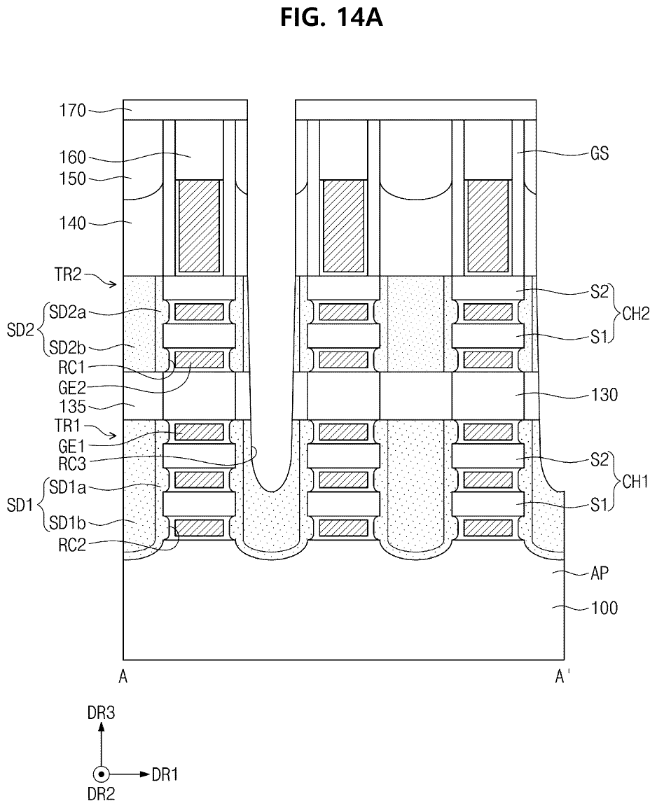

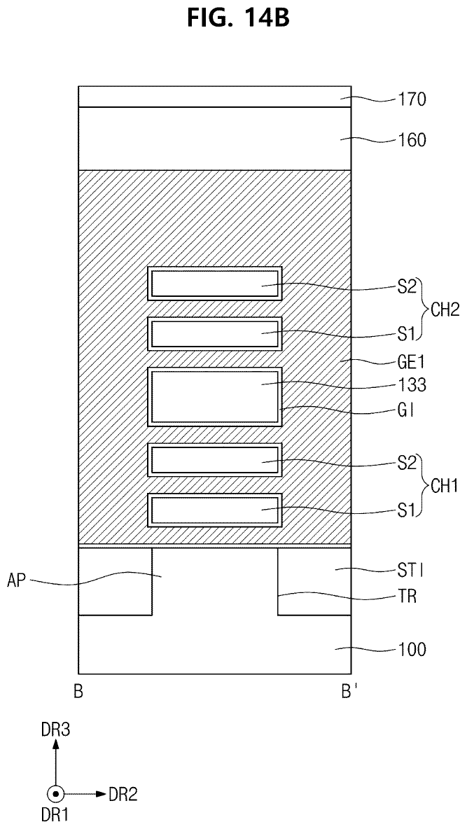

Referring to FIGS. 14A and 14B, a third recess RC3 may be formed in the first and second source/drain patterns SD1 and SD2 that are vertically stacked on the active pattern AP. The third recess RC3 may vertically penetrate through the second source/drain pattern SD2 and the additional isolation pattern 135, and may have a shape recessed vertically downward from the upper surface of the first source/drain pattern SD1.

For example, the third recess RC3 may vertically penetrate through the second interlayer insulating layer 170, the protective insulating pattern 150, the gate capping pattern 160, the second source/drain pattern SD2, and the additional isolation pattern 135, and may have a shape recessed vertically downward from the upper surface of the first source/drain pattern SD1.

The third recess RC3 may have a diameter varying in the vertical direction. The third recess RC3 may decrease in diameter in a vertical direction from an upper side to a lower side. The variation in diameter of the third recess RC3 depending on the vertical location may be due to a process margin or may be intended by design. When a recess is formed with a vertically elongated shape, a diameter of the recess may decrease downward due to a difference in etching rates between an upper portion and a lower portion.

In one or more embodiments, the third recess RC3 may be formed to have a smaller diameter than the second epitaxial layer SD2b in the second source/drain pattern SD2, and may be provided in the second epitaxial layer SD2b in the second source/drain pattern SD2. A portion of the second epitaxial layer SD2b may be exposed to the outside. However, the shape of the third recess RC3 is not limited thereto, and the third recess RC3 may be formed to have a larger diameter than the second epitaxial layer SD2b in the second source/drain pattern SD2. The third recess RC3 may be formed in the first epitaxial layer SD2a in the second source/drain pattern SD2, and a portion of the first epitaxial layer SD2a may be exposed. Also, even when the third recess RC3 is formed to have a smaller diameter than the second epitaxial layer SD2b in the second source/drain pattern SD2, a portion of the location may be shifted within a process error. At least a portion of the third recess RC3 may be formed in the first epitaxial layer SD2a in the second source/drain pattern SD2. In one or more embodiments, the third recess RC3 may be formed in the second epitaxial layer SD2b and/or the second epitaxial layer SD2b in the first source/drain pattern SD1.

In one or more embodiments, the formation of the third recess RC3 may cause the second epitaxial layer SD2b in the second source/drain pattern SD2 to be excessively removed. Thus, only a small amount of the second epitaxial layer SD2b may remain, or the second epitaxial layer SD2b may be substantially all removed and only the first epitaxial layer SD2a may remain. In a situation in which only a small amount of the second epitaxial layer SD2b remains in the third recess RC3, or the second epitaxial layer (SD2b) is substantially removed and only the first epitaxial layer SD2a remains, when the first contact CT1 is then formed, the contact resistance between the first contact CT1 and the second source/drain pattern SD2 may increases.

In one or more embodiments of the present invention, a process of forming a relatively heavily-doped third epitaxial layer SD2c is performed to reduce the contact resistance between the first contact CT1 and the second source/drain pattern SD2.

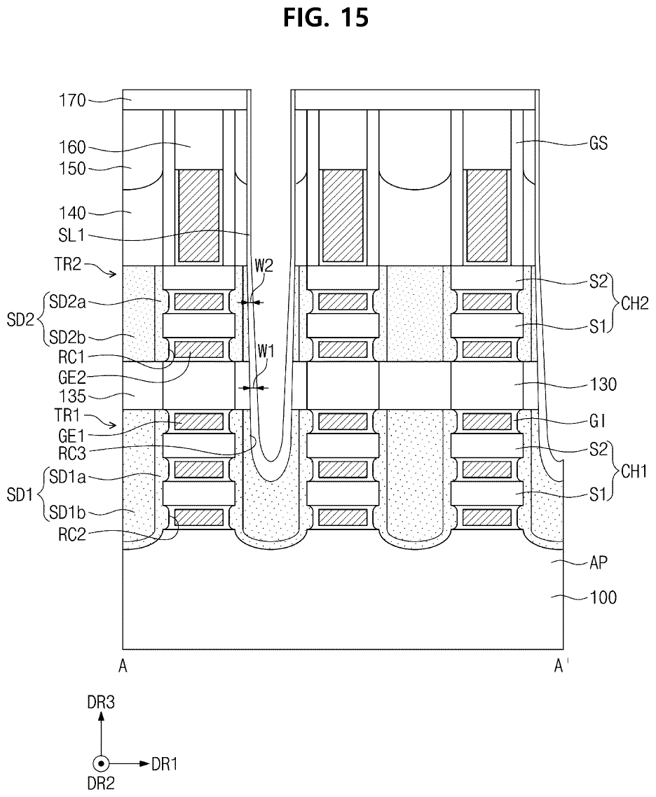

Referring to FIG. 15, a first sacrificial insulating layer SL1 may be formed in the second recess RC2. The first sacrificial insulating layer SL1 may correspond to a pattern for temporarily protecting the first source/drain pattern SD1 through a sequent partial etching process.

The first sacrificial insulating layer SL1 may be formed of a silicon oxide. However, a material of the first sacrificial insulating layer SL1 is not limited thereto, and another material may be used as long as it may temporarily protect the first source/drain pattern SD1 through a partial etching process.

The first sacrificial insulating layer SL1 may have a thickness varying depending on a vertical location. For example, the first sacrificial insulating layer SL1 may have a thickness increased in a vertical direction from an upper side to a lower side. A thickness of the first sacrificial insulating layer SL1 refers to a thickness in the vertical direction from a surface of the third recess RC3. The third recess RC3 has a diameter decreased in a direction from an upper side to a lower side, so that the first sacrificial insulating layer SL1 may be formed to have a greater thickness in the lower direction. For example, a thickness of the first sacrificial insulating layer SL1 on the first source/drain pattern SD1 may be greater than a thickness of the first sacrificial insulating layer SL1 on the second source/drain pattern SD2. If a thickness of the first sacrificial insulating layer SL1 on the first source/drain pattern SD1 is a first thickness W1 and a thickness of the first sacrificial insulating layer SL1 on the second source/drain pattern SD2 is a second thickness W2, then the first thickness W1 may be greater than the second thickness W2.

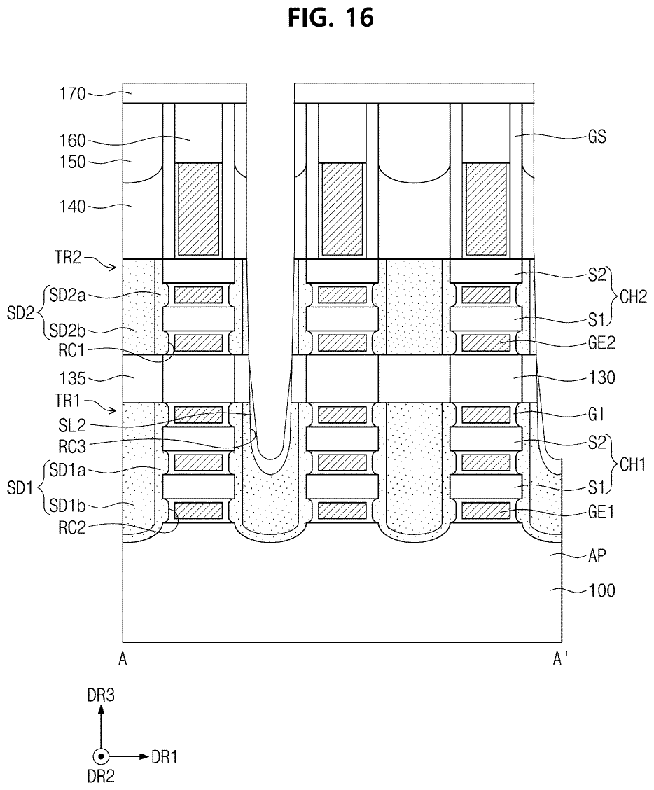

Referring to FIG. 16, a portion of the first sacrificial insulating layer SL1 is removed to form a second sacrificial insulating layer SL2. The first sacrificial insulating layer SL1 may be etched until a portion of the first sacrificial insulating layer SL1 on the first source/drain pattern SD1 remains and the first sacrificial insulating layer SL1 on the second source/drain pattern SD2 is completely removed. Etching of the first sacrificial insulating layer SL1 may be performed isotropically or anisotropically. The first sacrificial insulating layer SL1 has a greater thickness on the first source/drain pattern SD1 than on the second source/drain pattern SD2, so that even when the first sacrificial insulating layer SL1 is etched, the first sacrificial insulating layer SL1 on the second source/drain pattern SD2 may be removed without removing a portion of the first sacrificial insulating layer SL1 on the first source/drain pattern SD1.

The operation of etching a portion of the first sacrificial insulating layer SL1 may be performed by dry etching. For example, a portion of the first sacrificial insulating layer SL1 may be removed using plasma dry etching. The dry etching method may include various conditions of dry etching, for example, a plasma-assisted dry etching referred to as SiCoNi etching.

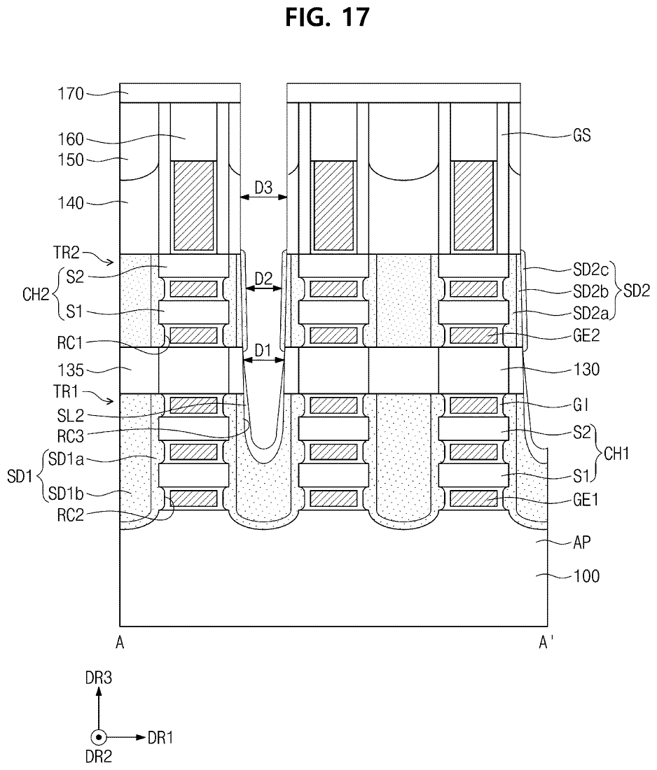

Referring to FIG. 17, a third epitaxial layer SD2c may be formed in the third recess RC3. The third epitaxial layer SD2c may be epitaxially grown from the second source/drain pattern SD2 in a horizontal direction and may protrude inwardly of the third recess RC3.

The third epitaxial layer SD2c may be selectively grown using inner walls of the second source/drain patterns SD2 exposed by the third recess RC3 as a seed. For example, the third epitaxial layer SD2c may be selectively grown using inner walls of the first epitaxial layer SD2a and/or the second epitaxial layer SD2b exposed by the third recess RC3 as a seed.

In one or more embodiments, a selective epitaxial growth process may include a chemical vapor deposition (CVD) process or a molecular beam epitaxy (MBE) process. The first source/drain patterns SD1 are covered by the second sacrificial insulating layer SL2, so that epitaxial growth does not occur. In one or more embodiments, the third epitaxial layer SD2c may be formed using substantially the same process as the second SEG process.

The third epitaxial layer SD2c may contain a relatively high concentration of germanium. For example, a concentration of germanium of the third epitaxial layer SD2c may be from about 20 at % to about 100 at %, for example, from about 30 at % to about 70 at %. During the formation of the third epitaxial layer SD2c, impurities may be injected in-situ into the second source/drain patterns SD2. For example, impurities may be injected into the third epitaxial layer SD2c after the third epitaxial layer SD2c is formed.

In one or more embodiments of the present invention, an N-type impurity may be highly doped into the patterns of the third epitaxial layer SD2c. For example, the N-type impurity may be phosphorus, arsenic, or antimony.

An impurity concentration of the third epitaxial layer SD2c may be higher than an impurity concentration of the first and/or second epitaxial layer SD2a and SD2b. Or, an impurity concentration of the third epitaxial layer SD2c may be substantially the same as an impurity concentration of the second epitaxial layer SD2b.

Due to the formation of the third epitaxial layer SD2c, the third recess RC3 may have a diameter varying depending on a vertical location. Accordingly, the third recess RC3 may have a bottle neck shape. For example, a diameter of the third recess RC3 may have a different value depending on a vertical level in an upward direction from the substrate 100. If a diameter of the third recess RC3 at a point on the first source/drain pattern SD1 is a first diameter D1 and a diameter of the third recess RC3 at a point on the second source/drain pattern SD2 is a second diameter D2, then the second diameter D2 may be smaller than the first diameter D1. Also, if a diameter of the third recess RC3 at a point on the first interlayer insulating layer 140 is a third diameter D3, then the second diameter D2 may be smaller than the third diameter D3.

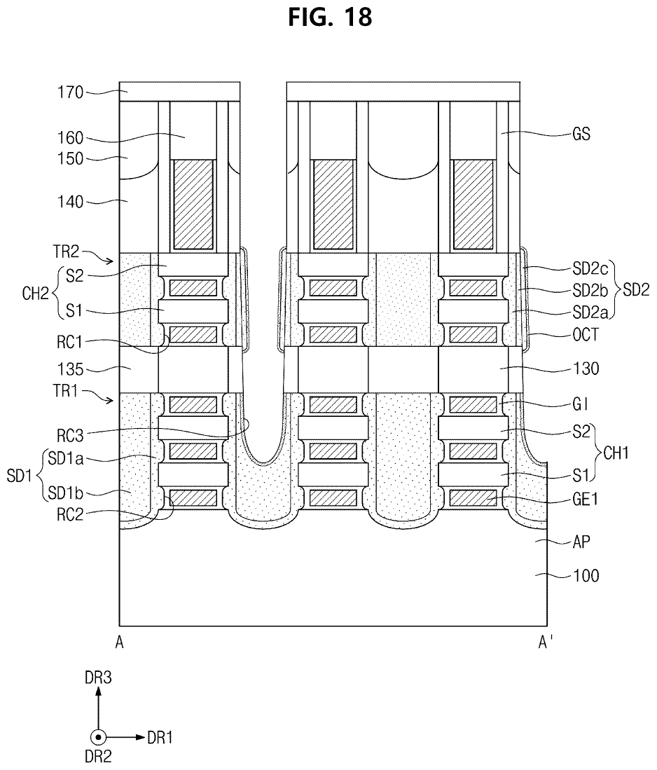

Referring to FIG. 18, the second sacrificial insulating layer SL2 on the first source/drain pattern SD1 may be removed. The second sacrificial insulating layer SL2 may be removed by various methods such as dry etching or wet etching. For example, the second sacrificial insulating layer SL2 may be removed by dry etching. For example, the second sacrificial insulating layer SL2 may be removed using plasma dry etching. For example, the dry etching may include plasma-assisted dry etching referred to as SiCoNi etching. Removing the second sacrificial insulating layer SL2 may lead to exposure of an upper surface of the first source/drain pattern SD1 within the third recess RC3.

Next, an ohmic contact layer OCT may be selectively formed on the first source/drain pattern SD1 and the second source/drain pattern SD2 that are exposed in the third recess RC3. The ohmic contact layer OCT may be formed to have a low contact resistance between a contact and the first and/or second source/drain patterns SD1 and SD2 later. The ohmic contact layer OCT may include a metal silicide. In one or more embodiments, the metal silicide may be formed of a material such as CoSi, NiSi, TiSi, NiPtSi, or NiTiSi. The ohmic contact layer OCT may be selectively formed only on the first source/drain pattern SD1 and the second source/drain pattern SD2 by forming a metal layer, performing an annealing, and then removing a remaining metal.

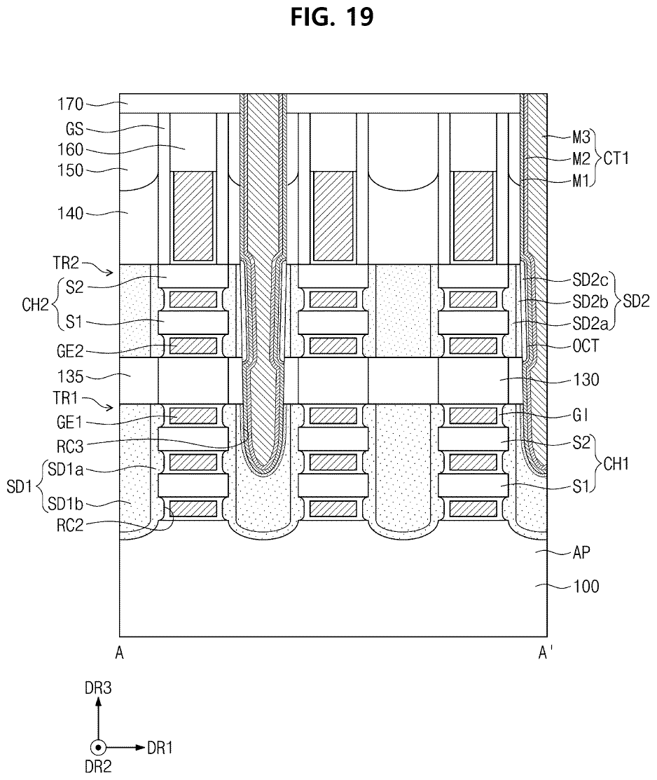

Referring to FIG. 19, a conductive material may be formed in the third recess RC3 to form a first contact CT1.

A method of forming a conductive material in the third recess RC3 is not limited, and various methods may be used. For example, an operation of forming a conductive material in the third recess RC3 may be performed by a chemical vapor deposition method.

The first contact CT1 may be formed of a single conductive material, but embodiments are not limited thereto. The first contact CT1 may include a plurality of conductive materials. The conductive material may include a metal and/or a metal nitride. The metal may be selected from Ti, W, Ru, Nb, Mo, Hf, Ni, Co, Pt, Yb, Tb, Dy, Er, or Pd. The metal nitride may be selected from TiN or TaN.

The first contact CT1 may be formed to have a multilayer structure. In one or more embodiments, the first contact CT1 may have a double-layer structure or a triple-layer structure. When the first contact CT1 has a double-layer structure, the first conductive layer M1 may be a barrier layer and the second conductive layer M2 may be a contact plug disposed on the barrier layer. When the first contact CT1 has a triple-layer structure, the first contact CT1 may include the first to third conductive layers M1, M2, and M3. At least one of the first to third conductive layers M1, M2, and M3 may include a material different from a material of a remaining layer. In one or more embodiments, the first conductive layer M1 may include titanium, the second conductive layer M2 may include titanium nitride, and the third conductive layer M3 may include cobalt.

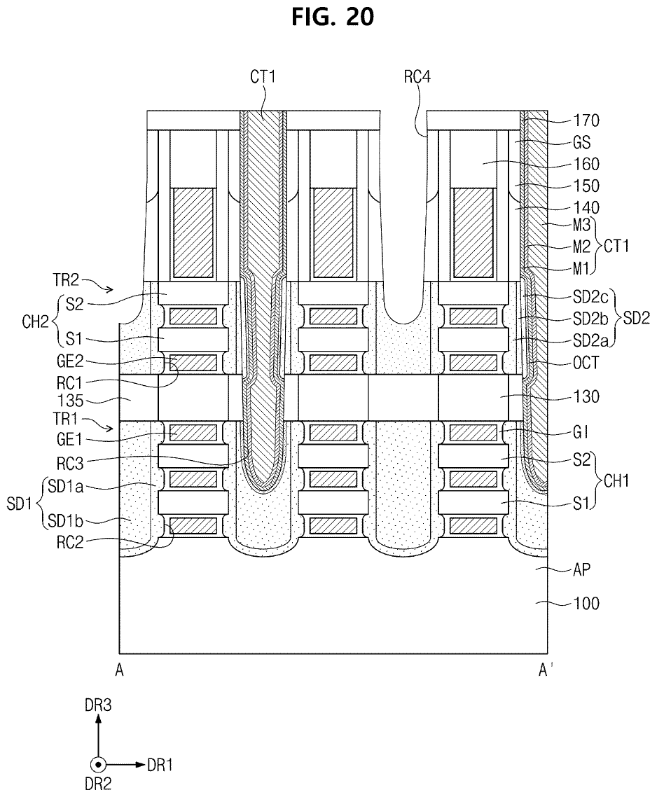

Referring to FIG. 20, an additional recess, for example, a fourth recess RC4, may be formed in the second source/drain patterns SD2. The fourth recess RC4 may have a shape recessed vertically downward from an upper surface of the second source/drain pattern SD2. For example, the fourth recess RC4 may penetrate through the second interlayer insulating layer 170, the protective insulating pattern 150, and the gate capping pattern 160, and may have a shape recessed vertically downward from the upper surface of the second source/drain pattern SD2.

The fourth recess RC4 may also have a diameter decreased in a vertical direction from an upper side to a lower side. However, a vertical depth of the fourth recess RC4 is smaller than that of the third recess RC3, so that a difference in diameter of the fourth recess RC4 depending on the vertical location may be relatively smaller than that of the third recess RC3.

In one or more embodiments, the fourth recess RC4 may be formed in the second epitaxial layer SD2b in the second source/drain pattern SD2. In one or more embodiments, the third recess RC3 may also be formed in the first epitaxial layer SD2a in the first source/drain pattern SD1.

In one or more embodiments, the fourth recess RC4 may not have a bottle neck shape, but embodiments are not limited thereto. Similarly to the third recess RC3, the fourth recess RC4 may also have a bottle neck shape. An additional third epitaxial layer SD2c epitaxially grown from the second source/drain pattern SD2 may be formed.

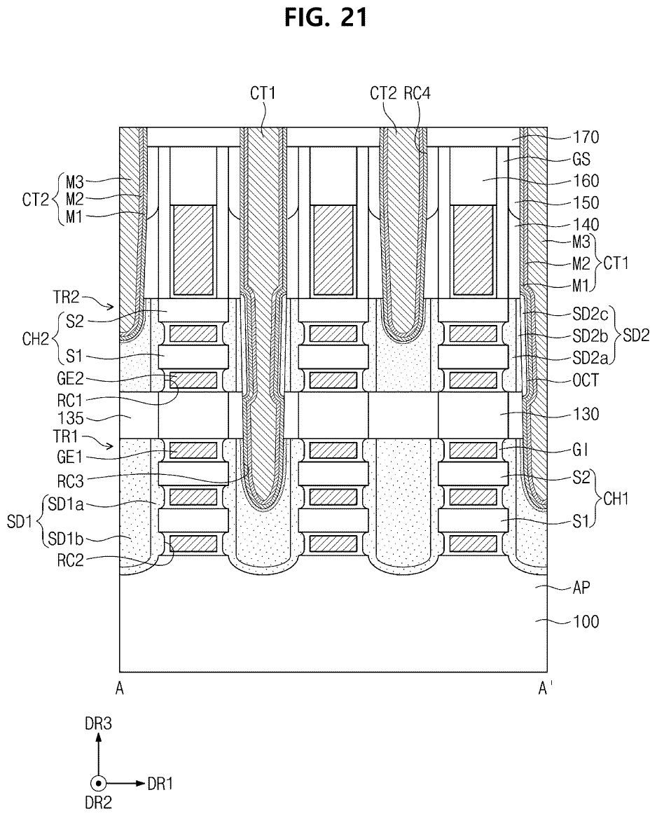

Referring to FIG. 21, an ohmic contact layer OCT may be selectively formed on the second source/drain pattern SD2 exposed in the fourth recess RC4. The ohmic contact layer OCT may include a metal silicide. The ohmic contact layer OCT may be selectively formed only on the second source/drain pattern SD2 by forming a metal layer, performing an annealing, and then removing a remaining metal. A conductive material is formed in the fourth recess RC4 to form a second contact CT2.

A method of forming a conductive material in the fourth recess RC4 is not limited, and various methods may be used. For example, an operation of forming a conductive material in the fourth recess RC4 may be performed by a chemical vapor deposition method.

The second contact CT2 may be formed of a single conductive material, but embodiments are not limited thereto. The second contact CT2 may include a plurality of conductive materials. The conductive material may include a metal and/or a metal nitride. The metal may be selected from Ti, W, Ru, Nb, Mo, Hf, Ni, Co, Pt, Yb, Tb, Dy, Er, or Pd. The metal nitride may be selected from TiN or TaN.

The first contact CT1 may be formed to have a multilayer structure. In one or more embodiments, the first contact CT1 may include the first to third conductive layers M1, M2, and M3. At least one of the first to third conductive layers M1, M2, and M3 may include a material different from a material of a remaining layer. In one or more embodiments, the first conductive layer M1 may include titanium, the second conductive layer M2 may include titanium nitride, and the third conductive layer M3 may include cobalt.

In one or more embodiments, the second contact CT2 may include substantially the same material as the first contact CT1 and may be formed to have substantially the same shape as the first contact CT1.

As set forth above, according to embodiments, a contact resistance between a source/drain electrode of the field-effect transistor and a contact may be reduced to secure the stable performance of the field-effect transistor. Accordingly, reliability of a semiconductor device may be improved.

While various embodiments have been shown and described above, it will be apparent to those skilled in the art that modifications and variations could be made without departing from the scope of the present inventive concept as defined by the appended claims.

What is claimed is:

1. A semiconductor device comprising:
first source/drain patterns disposed at a first level in a substantially vertical direction on a substrate;
a first channel pattern connected to the first source/drain patterns;
second source/drain patterns disposed at a second level higher than the first level;
a second channel pattern connected to the second source/drain patterns;
a gate electrode on the first and second channel patterns; and
a contact substantially vertically connected to at least one of the first and second source/drain patterns,
wherein:
the contact is provided in a bottleneck shape having a smaller diameter at the second level than a diameter at levels other than the second level.

2. The semiconductor device of claim 1, wherein:
the contact comprises a first contact connected to at least one of the first source/drain patterns; and
the first contact has a first diameter at the first level and a second diameter, smaller than the first diameter, at the second level.

3. The semiconductor device of claim 2, wherein:
the first contact substantially vertically penetrates through at least one of the second source/drain patterns to be connected to at least one of the first source/drain patterns.

4. The semiconductor device of claim 2, wherein:
the first contact has a third diameter on a third level higher than the second level, wherein the third diameter is larger than the second diameter.

5. The semiconductor device of claim 2, wherein:
at least one of the second source/drain patterns is epitaxially grown in a substantially horizontal direction to protrude toward the contact.

6. The semiconductor device of claim 2, further comprising:
an ohmic contact layer provided between the second source/drain patterns and the contact.

7. The semiconductor device of claim 1, wherein:
each of the second source/drain patterns comprises a first pixel layer and a second epitaxial layer having different impurity concentrations.

8. The semiconductor device of claim 7, wherein:
in each of the second source/drain patterns, the second epitaxial layer has a higher impurity concentration than an impurity concentration of the first epitaxial layer.

9. The semiconductor device of claim 8, wherein:
at least one of the second source/drain patterns comprises a third epitaxial layer epitaxially grown in a substantially horizontal direction from the first and/or second epitaxial layers to protrude toward the contact.

10. The semiconductor device of claim 9, wherein:
the third epitaxial layer has an impurity concentration, higher than or equal to an impurity concentration of the second epitaxial layer.

11. The semiconductor device of claim 1, wherein:
the contact further comprises a second contact connected to the second source/drain pattern.

12. The semiconductor device of claim 1, further comprising:
a gate insulating layer provided between the gate electrode and the first channel pattern and between the gate electrode and the second channel pattern.

13. The semiconductor device of claim 12, wherein:
the first source/drain patterns, the first channel pattern, and the gate electrode form a first transistor;
the second source/drain patterns, the second channel pattern, and the gate electrode form a second transistor; and
one of the first and second transistors is an NMOS transistor, and the other is a PMOS transistor.

14. The semiconductor device of claim 13, wherein:
the first transistor is a PMOS transistor, and the second transistor is an NMOS transistor.

15. The semiconductor device of claim 1, further comprising:
intermediate isolation patterns provided between the first channel pattern and the second channel pattern.

16. The semiconductor device of claim 1, wherein:
the first source/drain patterns and the second source/drain patterns overlap in a substantially vertical direction.

17. The semiconductor device of claim 1, wherein:
at least one of the first and second channel patterns comprises a plurality of semiconductor patterns, substantially vertically stacked and spaced apart from one another.

18. The semiconductor device of claim 17, wherein:
the gate electrode surrounds each of the semiconductor patterns of a corresponding channel pattern, among the first and second channel patterns.

19. A contact structure comprising:
a first source/drain pattern;
a second source/drain pattern stacked on the first source/drain pattern; and
a contact penetrating through the second source/drain pattern and provided in a recess recessed from an upper surface of the first source/drain pattern,
wherein:
the contact is provided in a bottleneck structure having a first diameter at a point in the first source/drain pattern and a second diameter smaller than the first diameter at a point in the second source/drain pattern.

20. A semiconductor device comprising:
a first transistor provided on a substrate and comprising a first source/drain pattern;
a second transistor stacked on the first transistor and comprising a second source/drain pattern overlapping the first source/drain pattern; and
a contact disposed substantially vertically within the first and second source/drain patterns,
wherein:
the second source/drain pattern comprises:
a first epitaxial layer having a first impurity concentration;
a second epitaxial layer having a second impurity concentration higher than the first impurity concentration; and
a third epitaxial layer protruding inwardly of the contact and having a third impurity concentration higher than the first impurity concentration; and
the contact has a smaller diameter in a region, in which the third epitaxial layer is provided, than a diameter in another region adjacent to the region.
